(19) United States
(12) Patent Application Publication
(10) Pub. No.: US 2025/0165678 A1
(43) Pub. Date: May 22, 2025

(54) USE A GENERATIVE MODEL TO CREATE SYNTHETIC USERS FOR TESTING AND ANALYSIS

(71) Applicant: Roku, Inc., San Jose, CA (US)

(72) Inventors: Gak Wee Low, Sunnyvale, CA (US); Sunil Ramesh, Saratoga, CA (US); Michael Patrick Cutter, Golden, CO (US); Andrew Peter Fogg, Los Gatos, CA (US); Michael Richard Sanders, Cambridge (GB)

(73) Assignee: Roku, Inc., San Jose, CA (US)

(21) Appl. No.: 18/511,873

(22) Filed: Nov. 16, 2023

(51) Int. Cl. G06F 30/27

(52) U.S. Cl. CPC G06F 30/27

(57) ABSTRACT

Conducting user research with human users is time consuming and expensive. Provided with quality training data that represents human users having different personae, models can be trained to offer responses that can emulate different human users. The models may offer synthetic users that can extract information from and respond to inputs to the models. The inputs can include prompts and responses can include answers to the prompts. In some cases, data about human users can be used to build different synthetic user memories, which may be used to generate different prompt chains corresponding to different users. The prompt chain can be used to prompt a model to respond based on the contextual information in the synthetic user memory.

### TECHNICAL FIELD

This disclosure relates generally to modeling and extracting feedback from synthetic users, and more specifically, using machine learning to learn from user data and using machine learning models to model and extract feedback from synthetic users.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates using synthetic users to conduct user research, according to some embodiments of the disclosure.

FIG. 2 illustrates using synthetic users for content understanding, according to some embodiments of the disclosure.

FIG. 3 illustrates using synthetic users for analyzing device-related user behaviors, according to some embodiments of the disclosure.

FIG. 4 illustrates training a model using training data, according to some embodiments of the disclosure.

FIG. 5 illustrates training a model using training data and transfer learning, according to some embodiments of the disclosure.

FIG. 6 illustrates transforming user data into training data, according to some embodiments of the disclosure.

FIG. 7 illustrates inputting prompts and receiving responses from synthetic users, according to some embodiments of the disclosure.

FIG. 8 illustrates cluster analysis based on feedback from synthetic users, according to some embodiments of the disclosure.

FIG. 9 illustrates user data used to build synthetic user memories, according to some embodiments of the disclosure.

FIG. 10 illustrates creating synthetic user memory, according to some embodiments of the disclosure.

FIG. 11 illustrates evaluation of a generated response and modification of synthetic user memory, according to some embodiments of the disclosure.

FIG. 12 illustrates obtaining synthetic population responses and analyzing thereof, according to some embodiments of the disclosure.

FIG. 13 is a flow chart illustrating methods for training a model, and analyzing responses from the model, according to some embodiments of the disclosure.

FIG. 14 is a flow chart illustrating methods for exploratory cluster analysis, according to some embodiments of the disclosure.

FIG. 15 is a flow chart illustrating methods for content understanding, according to some embodiments of the disclosure.

FIG. 16 is a flow chart illustrating methods for prompt chaining to create synthetic user memories, according to some embodiments of the disclosure.

FIG. 17 is a flow chart illustrating methods for refining synthetic user memories, according to some embodiments of the disclosure.

FIG. 18 is a flow chart illustrating methods for completing an A/B feature test, according to some embodiments of the disclosure.

FIG. 19 is a block diagram of an exemplary computing device, according to some embodiments of the disclosure.

### DETAILED DESCRIPTION

### Overview

Conducting user research with human users is time consuming and expensive. A user research cycle can take four to six weeks to complete. The cycle may include activities such as recruiting human users, designing questionnaires and/or experiments, conducting interviews and/or experiments, analyzing results, and reporting the results. It can be difficult to test ad hoc ideas and concepts. It can be even more difficult to test ideas and concepts iteratively and repetitively. With human users, especially unpaid users, it can be difficult to get feedback since human users may sometimes skip or avoid having to answer questions or provide feedback. Feedback from human users may be biased towards negative feedback as well. Feedback from human users can be subject to other types of bias in the questionnaire and/or experiments. In many cases, feedback from human users may not accurately reflect true responses (e.g., there is a gap between what users say and what users do).

Provided with quality training data that represents human users having different personae, models can be trained to offer responses that can emulate different human users. Training data may come from user data (data about human users). User data may include data collected from a content streaming platform, including one or more of payment data, user interactivity data, user social network data, etc. User data may include user communication data, including one or more of: user interview transcripts, customer care call transcripts, customer care emails, customer care chats, customer care feedback, etc. User data may include one or more of: market research data, user research data, etc. Some user data may be transformed into training data having a format that is suitable for training a model that can perform a certain task. In some cases, training data can include prompts and responses.

Herein, persona refers to a user having a set of features or characteristics. Different personae would have one or more differences in the features or characteristics. Sone features or characteristics may be discrete. Some features or characteristics may be continuous. Examples of features or characteristics may relate to demographics, age, location, language, gender, family status, religion, culture, income level, education level, pollical affiliation, race, homeowner or renter, preference(s), affinity (-ies), psychological profile, needs(s), alternative abilities, accessibility needs, requirements, experience(s), past behavior(s), expectation(s), job title, job history, device(s) used, software system(s) used, role(s), etc.

Training data may represent different personae of human users, e.g., as characterized by human users' responses and actions. Different sources or types of user data may be used in combination as training data to represent different personae of human users in a well-rounded way. In some cases, training data associated with different personae may be weighted differently during training. In some cases, training data associated with different sources of user data may be weighted differently during training.

Models can learn patterns and insights about users with different personae that may not be apparent from data analysis. Models can deduce patterns and insights about synthetic users with different personae. Models can generate and output statistically likely or probable responses from synthetic users with different personae. Thus, models may offer synthetic users that can extract information from and respond to inputs to the models. The inputs can include prompts and responses can include answers to the prompts. The models can extract and output feature vectors about the inputs, which may represent how a synthetic user may interpret a particular input.

Such models have wide applicability. Some models can produce speech-like text responses to inputs, which can be used to allow synthetic users to participate in user research and/or feature testing (e.g., generate synthetic user feedback). Some models can produce feature vectors and/or responses to inputs, which can be used for other applications such as exploratory cluster analysis and content analysis.

In some cases, data about human users can be used to build different synthetic user memories. Synthetic user memories can be used with a model to create a population of synthetic users. User data about human users that can be used to build synthetic user memories may include focus group data. User data about human users that can be used to build synthetic user memories may include user interactivity data logged during A/B testing, e.g., A/B feature testing of features on a content streaming platform. User data about human users that can be used to build synthetic memories may include structured and/or unstructured data about various users, e.g., users of a content streaming platform.

The user data about a particular user can be converted into natural language entries of a memory log of a synthetic user. The memory log may enable storage of information that a synthetic user may remember. From the memory log, a subset of natural language entries can be extracted (e.g., using an extraction function) and presented to a model. The model can use the subset of entries as memories and generate opinions about the memories. The model can explain the reasoning behind an action performed in response to the subset of entries as memories. The model can perform high-level abstract reasoning about the subset of entries as memories. Responses from the model in response to the subset of entries can be incorporated into the memory log. The memory log may capture one or more of: facts, events, actions based on the user data. The memory log may capture responses generated by the model, including one or more of: statements, reasoning, opinions, observations, and actions made by the model. The memory log can be a source of information about the user and the behavior of the user.

One or more responses can be used in subsequent prompts to the model having a subset of entries from the memory log. Using past responses from the model as input to the model can form a prompt chain. Different memory logs corresponding to different synthetic users having different generated responses incorporated therein may be used to generate different prompt chains corresponding to different users.

As used herein, a prompt chain may include one or more responses or outputs from a model and uses one or more responses or outputs as input to the next prompt to the model. Different prompt chains can be used to create a population of synthetic users. A prompt chain can prompt a model to respond based on the contextual information presented in the prompt chain. A prompt chain involving one or more responses or outputs of the model can force the model into a specific vectorial space to respond to the contextual information presented in the prompt chain. Using different prompt chains, the model may respond differently in view of the differences in contextual information presented in the prompt chain. Experiments can be conducted and/or simulated using a population of synthetic users created using different synthetic user memories and different prompt chains generated therefrom.

In some cases, the prompt chain may be refined based on known information available in the user data used to generate the memory log. A response from the model can be evaluated against an expected response obtained from the user data. The memory log may be modified based on the evaluation to fine tune prompt chains being generated from the memory log.

In some cases, the population of synthetic users may represent individual users of a content streaming platform. In some cases, the population of synthetic users may represent candidate users of a content streaming platform (e.g., a population of human users having a particular demographic). In some cases, the population of synthetic users may have a demographic distribution that matches a demographic distribution of a (general) population of human users.

Effectively, different prompt chains can create a population of synthetic users, and experiments can be simulated using the synthetic users. The events in the simulation can be generated and logged in the synthetic memories of the synthetic users. In some cases, stimulus can be applied in prompt chain to obtain responses to the stimulus from the population of synthetic users. The responses may be stored in different synthetic user memories. The synthetic user memories of various synthetic users built as a result of the simulation can be analyzed. Advantageously, sampling of a population may not be needed when using synthetic users, or dense sampling of the population can be performed, if user data is available for an entire population or dense sampling of users.

While users of a content streaming platform are presented in various examples illustrated herein, it is envisioned by the disclosure that the users may be users of consumer devices and/or Internet-of-Things devices.

### Exemplary Systems Involving Synthetic Users Modeled by One or More Machine Learning Models

One or more models can be trained using suitable training data and can embed or encode one or more synthetic users within the one or more models. The one or more models may include machine learning models, which can learn through supervised learning or unsupervised learning. With supervised learning, machine learning models can learn from training data and find patterns or insights from the training data. With unsupervised learning, machine learning models can find patterns or insights directly from the input data (without significant sets of training data).

Machine learning models can extract patterns or insights about synthetic users, such as synthetic users having different personae. Examples of machine learning models may include artificial neural networks, deep neural networks, recurrent neural networks, graph-processing neural networks, autoencoders, transformer-based neural networks, etc. Some machine learning models can perform classification. Some machine learning models can perform regression. Some machine learning models can perform feature extraction or encoding, e.g., produce feature vectors that represent the inputs in a particular feature space, based on patterns and insights learned about synthetic users, as synthetic users having different personae.

Some machine learning models, e.g., generative models, can generate new data that is based on patterns and insights learned from the training data used to train the models. Some generative models, e.g., encoder-decoder models, can encode an input into a vector representation of the input, and decode the vector representation of the input to generate an output. Some generative models, models can receive an input, such a stimulus or prompt, and generate an output such as a response or answer. Outputs of generative models can include images, videos, text, numbers, music, video, software code, designs, etc.

One example of such generative model is a large language model, which can receive a prompt (e.g., natural language question) as an input, and output a response (e.g., a natural language answer) to the prompt, based on patterns and insights that may be encoded in the large language model. Some generative models can be used to learn and encode patterns and insights about synthetic users, potentially synthetic users with different personae in the generative models. Such generative models can respond to input (e.g., prompt, stimulus, question, etc.) and produce an output (e.g., new data, reply, results, answer, or response) based on patterns and insights learned about synthetic users, such as synthetic users having different personae. The new data or response can represent likely, or probable answers, replies, or responses that synthetic users having different personae would make to the input.

One or more synthetic users may be represented by or modeled by one or more models (e.g., the parameters of the models). In some cases, a model can model or represent a synthetic user, such as a synthetic user having a particular persona. In some cases, a model can model or represent synthetic users having different personae. In some cases, different models can model or represent synthetic users having respective personae (e.g., one model per persona).

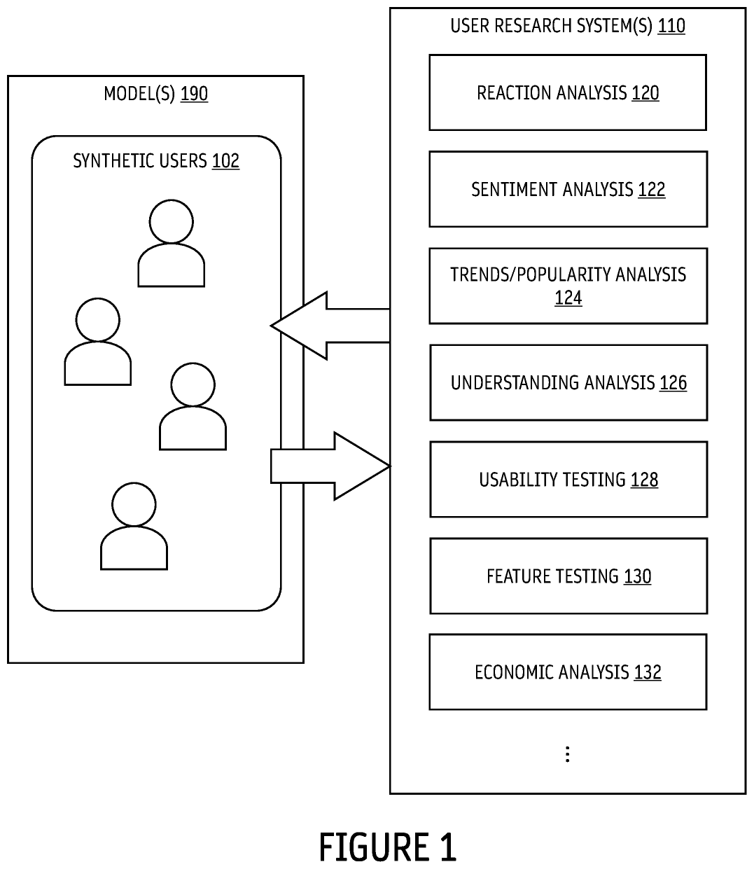

In the FIGURES, such as FIGS. 1-3, model(s) 190 may encode synthetic users 102, e.g., synthetic users having different personae. Model(s) 190 can receive inputs and produce outputs in response to the inputs. Inputs to model(s) 190 may, in some cases, include content. Content may include one or more of: media content, multi-media content, a description of content, metadata of content, idea, concept, notes, promotion, email, text message, image/graphic, system feature, user interface workflow, storyline, script, storyboard, audio clip, tv show, movie, game, description of features, user interface workflow, description of product, description of a device, description of device features, description of user interface, etc. Model(s) 190 may produce outputs based on patterns/insights about synthetic users 102, which may be encoded in the (trained/learned) parameters in model(s) 190. Outputs of model(s) 190 may be considered feedback from synthetic users 102. Systems may examine or analyze outputs from model(s) 190 to understand synthetic users 102 having a certain persona. Systems may aggregate outputs from model(s) 190 to understand synthetic users 102 having different personae. Systems may use outputs from model(s) 190 associated with synthetic users 102 having different personae to perform cluster analysis, comparison analysis, statistical analysis, population analysis, split testing or A/B testing, etc.

FIG. 1 illustrates using synthetic users 102 to conduct user research, according to some embodiments of the disclosure. User research system(s) 110 may interact with synthetic users 102 to perform one or more user research tasks, e.g., understanding how a user (or a typical user having a particular persona) would respond to certain content, understanding how a population of users (e.g., typical users with respective personas) would react to certain content, etc. Exemplary user research tasks may include one or more of: reaction analysis 120, sentiment analysis 122, trends/popularity analysis 124, understanding analysis 126, usability testing 128, feature testing 130, and economic analysis 132. Other user research tasks are envisioned by the disclosure. Components in user research system(s) 110 may examine/analyze the output of model(s) 190. User research tasks can examine response(s) output by model(s) 190, e.g., a response for a particular synthetic user, a series of responses (across time) for a particular synthetic user, a response for a typical synthetic user having a particular persona, a series of responses (across time) for a typical synthetic user having a particular persona, a response for a group, cohort, or population of synthetic users, and a series of responses (across time) for a group, cohort, or population of synthetic users.

User research system(s) 110 may include reaction analysis 120. Reaction analysis 120 may prompt synthetic users 102 to consume content and examine outputs of model(s) 190 to see how synthetic users 102 may react to the content. Reactions of synthetic users 102 may include one or more of: whether synthetic users 102 finds the content positive, neutral, or negative, whether synthetic users 102 likes or dislikes the content, whether synthetic users 102 pays attention to the content or not, synthetic users 102 finds the content relevant/interesting or not, whether synthetic users 102 would interact with the content or act upon the content, how long synthetic users 102 would pay attention to or focus on the content, whether synthetic users 102 would skip or ignore the content, whether synthetic users 102 react impulsively to the content, etc.

User research system(s) 110 may include sentiment analysis 122. Sentiment analysis 122 may prompt synthetic users 102 to consume content and examine outputs of model(s) 190 to see how synthetic users 102 may emotionally respond to the content, or what kind of sentiment or emotion did the synthetic users 102 extract or interpret from the content. Sentiment or emotions of synthetic users 102 may include one or more of: emotionally positive, emotionally neutral, emotionally negative, happiness, sadness, disgust, fear, surprise, shock, anger, joy, trustworthy, loving, hungry, thirsty, hot, cold, warm, witty, humorous, insulting, repulsive, awkward, weird, depressing, grief, jealous, regret, contempt, sympathetic, etc.

User research system(s) 110 may include trends/popularity analysis 124. Trends/popularity analysis 124 may prompt synthetic users 102 to consume content and examine outputs of model(s) 190 to assess whether many synthetic users 102 would find the content appealing or catchy. Outputs of model(s) 190 may indicate or suggest that certain content can become popular, gain widespread appeal, or gain appeal with a number of different personae.

User research system(s) 110 may include understanding analysis 126. Understanding analysis 126 may prompt synthetic users 102 to consume content and examine outputs of model(s) 190 to determine one or more of: whether synthetic users 102 understand the content or not, which part of the content the synthetic users 102 understand or not, what synthetic users 102 understand from the content, what synthetic users 102 would summarize from the content, what takeaways the synthetic users 102 understand from the content, what synthetic users 102 perceive as salient information or non-salient information, etc.

User research system(s) 110 may include usability testing 128. Usability testing 128 may prompt synthetic users 102 to consume content (e.g., description of features, user interface workflow, description of product, description of user interface, etc.), and examine outputs of model(s) 190 to determine one or more of: whether synthetic users 102 understand how to use the content, expected behavior(s) of the synthetic users 102 with the content, what synthetic users 102 may identify as good features, or bad features, what synthetic users 102 may consider as areas for improvement, what the user experiences are for synthetic users 102, whether behaviors of synthetic users 102 are consistent, whether synthetic users 102 find the content confusing or not, what synthetic users 102 pay attention to, a number of interactions needed for a synthetic user 102 to perform a task, whether synthetic users 102 would prefer/rank one content over another, etc.

User research system(s) 110 may include feature testing 130. Feature testing 130 may prompt synthetic users 102 to consume content (e.g., description of features, user interface workflow, description of product, description of user interface, etc.), and examine outputs of model(s) 190 to determine one or more of: whether synthetic users 102 finds the content effective, whether synthetic users 102 finds the content useful, whether synthetic users 102 finds the content to meet a level of quality, whether synthetic users 102 finds the content problematic, whether synthetic users 102 may respond differently to different features, whether synthetic users 102 would return, whether synthetic users 102 would prefer/rank one content over another, etc.

User research system(s) 110 may include economic analysis 132. Economic analysis 132 may prompt synthetic users 102 to consume content (e.g., description of promotion, description of advertisement, pricing, description of a check out flow, description of user interface, description of offer, etc.), and examine outputs of model(s) 190 to determine one or more of: whether synthetic users 102 would make a purchase or not, whether synthetic users 102 would subscribe or not, whether synthetic users 102 would subscribe or not, a price point or price range that is acceptable to synthetic users 102, whether synthetic users 102 believes the price point or price range is a bargain, whether synthetic users 102 would return, how long whether synthetic users 102 may stay as a subscriber, whether synthetic users 102 would prefer/rank one content over another, etc.

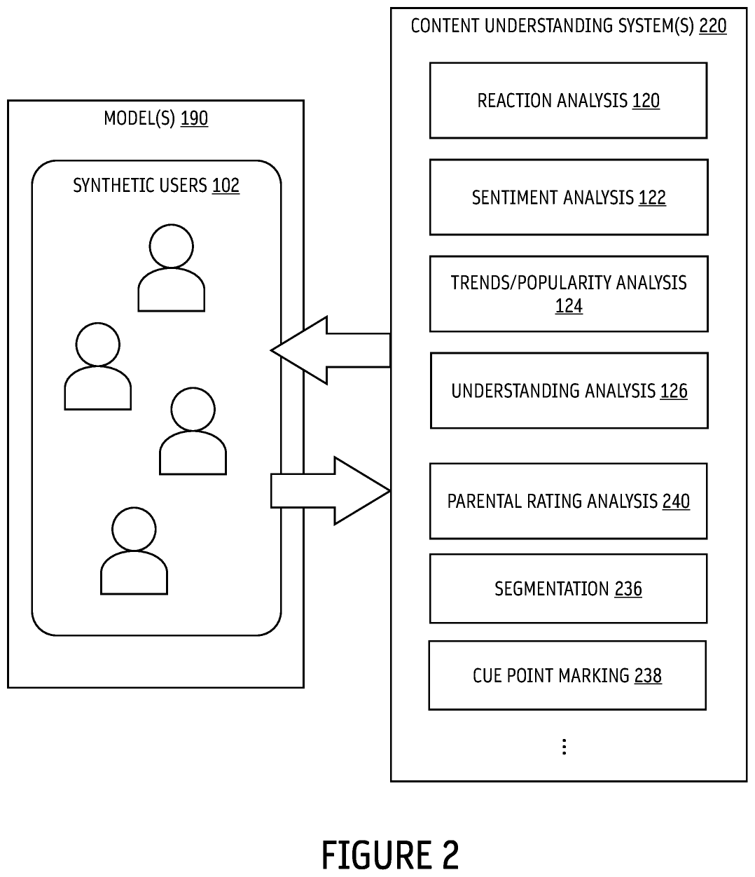

FIG. 2 illustrates using synthetic users 102 for content understanding, according to some embodiments of the disclosure. Content understanding system(s) 220 may interact with synthetic users 102 to perform content processing tasks, e.g., autonomously annotating and understanding content without requiring a human in the loop, generating metadata about content, extracting feature vectors about content, identifying salient features in the content, identifying non-salient features in the content, determining reaction of synthetic users 102, determining sentiment of content perceived by synthetic users 102, segmenting content, marking cue points in content, etc. Exemplary content processing tasks may include one or more of: reaction analysis 120, sentiment analysis 122, trends/popularity analysis 124, understanding analysis 126, parental rating analysis 20, segmentation 236, and cue point marking 238. Other content processing tasks are envisioned by the disclosure.

Content understanding system(s) 220 may include one or more same/similar components as user research system(s) 110, such as reaction analysis 120, sentiment analysis 122, trends/popularity analysis 124, understanding analysis 126, etc.

Content understanding system(s) 220 may include parental rating analysis 240. Parental rating analysis 240 may prompt synthetic users 102 to consume content (e.g., audio, video, text), and examine outputs of model(s) 190 to determine one or more of: whether synthetic users 102 may believe the content is appropriate for a certain age group, which age group the synthetic users 102 believe the content is appropriate for, whether synthetic users 102 may believe the content is inappropriate for a certain age group, whether synthetic users 102 may believe the content is inappropriate for a certain demographic, whether synthetic users 102 may believe the content should be censored, whether synthetic users 102 may believe the content is recommended for a certain age group, whether synthetic users 102 may believe the content is recommended for a certain demographic, etc.

Content understanding system(s) 220 may include segmentation 236. Segmentation 236 may prompt synthetic users 102 to consume content (e.g., audio, video, text), and examine outputs of model(s) 190 to determine one or more of: general context or understanding interpreted by synthetic users 102, whether the synthetic users 102 perceive a change in general context or understanding in the content, whether the synthetic users 102 perceive multiple contexts or understanding separated in time in the content, whether the synthetic users 102 understand that the content has segments, etc.

Content understanding system(s) 220 may include cue point marking 238. Cue point marking 238 may prompt synthetic users 102 to consume content (e.g., audio, video, text), and examine outputs of model(s) 190 to determine one or more of: whether the synthetic users 102 perceive a change in the content, whether the synthetic users 102 perceive a natural end of a context or understanding in the content, whether the synthetic users 102 perceive a lull in the content, whether the synthetic users 102 perceive a peak in the content, whether the synthetic users 102 perceive a pause in the content, whether the synthetic users 102 perceive a break in the content, what the synthetic users 102 perceive as the sentiment in the content before the change/break/pause/lull in the content, whether the synthetic users 102 would find a break or pause in the content acceptable or not, etc. Cue point marking 238 may insert cue points or mark cue points in the content based on the outputs of model(s) 190. Cue points may be particularly suitable for inserting ancillary content such as a message to a human viewer, an advertisement, a trailer, a service announcement, a questionnaire, a game, alternative shots, commentary, augmented reality content, within the content. Cue point marking 238 may insert cue points or mark cue points which are specific to synthetic users 102 having a certain persona. Cue point marking 238 may insert cue points or mark cue points which are specific to synthetic users 102 (e.g., having a certain persona) perceiving a certain sentiment. Cue point marking 238 may insert cue points or mark cue points which are generic to (or appropriate to most) synthetic users 102 or synthetic users 102 having a range of different personae. Cue point marking 238 may insert cue points or mark cue points which are specific to the content being inserted at the cue point.

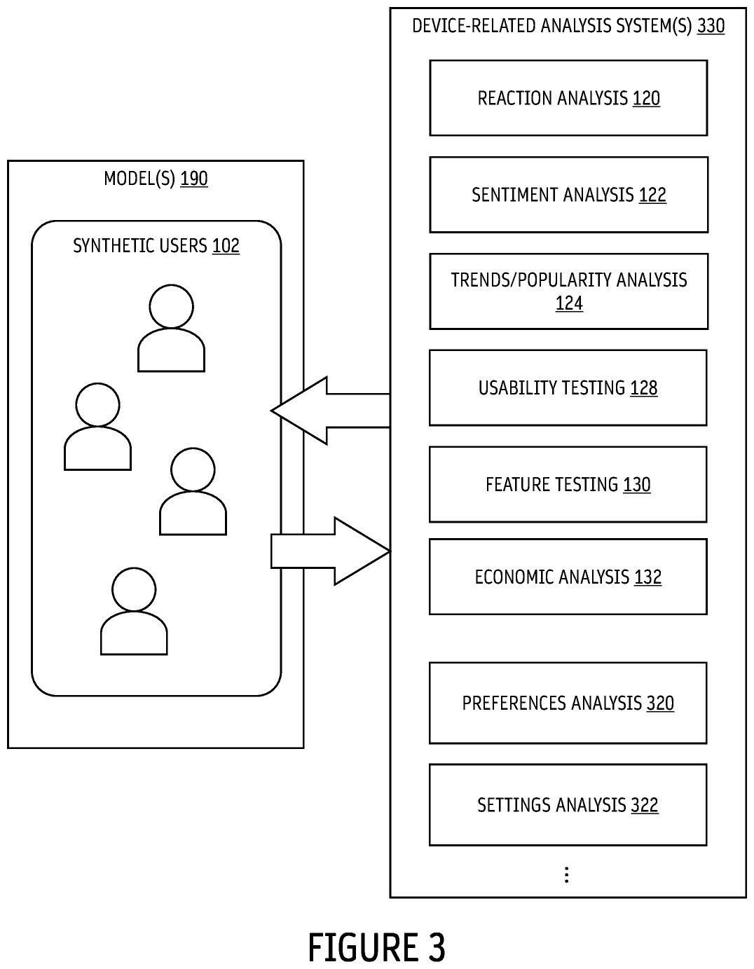

FIG. 3 illustrates using synthetic users 102 for analyzing device-related user behaviors, according to some embodiments of the disclosure. Device-related analysis system(s) 330 may interact with synthetic users 102 to perform device-related user behavior analysis tasks, e.g., determining whether synthetic users 102 would purchase a new device, determining whether synthetic users 102 would prefer certain user preferences over others, determining whether synthetic users 102 would prefer certain user settings over others, etc. Exemplary device-related user behavior analysis tasks may include one or more of: reaction analysis 120, sentiment analysis 122, trends/popularity analysis 124, understanding analysis 126, usability testing 128, feature testing 130, economic analysis 132, preferences analysis 320, and setting analysis 322. Other device-related user behavior analysis tasks are envisioned by the disclosure.

Device-related analysis system(s) 330 may include one or more same/similar components as user research system(s) 110, such as reaction analysis 120, sentiment analysis 122, trends/popularity analysis 124, usability testing 128, feature testing 130, economic analysis 132, etc.

Device-related analysis system(s) 330 may include preferences analysis 320. Preferences analysis 320 may prompt synthetic users 102 to consume content (e.g., description of device and description of preferences), and examine outputs of model(s) 190 to determine one or more of: determining whether synthetic users 102 would prefer certain preferences over others, determining whether synthetic users 102 would want to have adjustability for certain preferences, determining reactions synthetic users 102 may have with certain preferences, determining sentiment synthetic users 102 may have with certain preferences, determining economic responses that synthetic users 102 may have with certain preferences, etc.

Device-related analysis system(s) 330 may include settings analysis 322. Settings analysis 322 may prompt synthetic users 102 to consume content (e.g., description of device and description of settings), and examine outputs of model(s) 190 to determine one or more of: determining whether synthetic users 102 would prefer certain settings over others, determining whether synthetic users 102 would want to have adjustability for certain settings, determining reactions synthetic users 102 may have with certain settings, determining sentiment synthetic users 102 may have with certain settings, determining economic responses that synthetic users 102 may have with certain settings, etc.

### Training Models to Model Synthetic Users

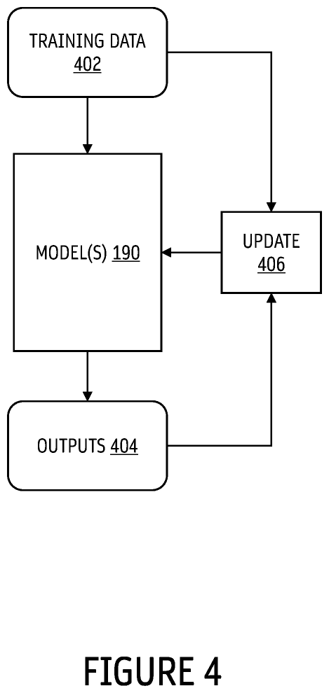

FIG. 4 illustrates training a model using training data, according to some embodiments of the disclosure. Model(s) 190 may be trained from scratch. Training data 402 may be provided as input to model(s) 190. Model(s) 190 may generate outputs 404. Desired or expected outputs in training data 402 and actual outputs 404 may be provided to update 406. Update 406 may update parameters of model(s) 190 in a manner to optimize the performance of model(s) 190 (e.g., precision, recall, accuracy/error, generalizability, consistency, confidence, etc.). Update 406 can compute a loss function based on an error between desired or expected outputs in training data 402 and actual outputs 404. Update 406 may cross validate the desired or expected outputs in training data 402 and actual outputs 404. Using the loss function, update 406 may update parameters of model(s) 190, e.g., to minimize the loss function.

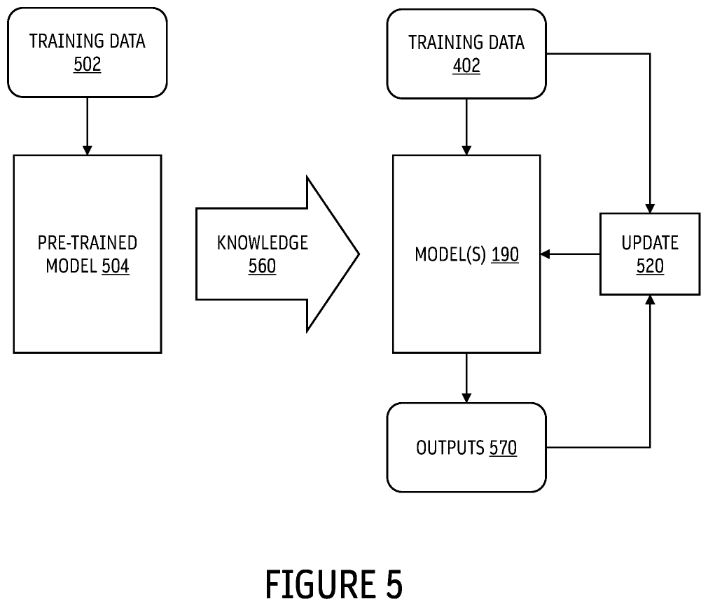

FIG. 5 illustrates training a model using training data and transfer learning, according to some embodiments of the disclosure. Transfer learning can be used to develop model(s) 190 with a reasonable amount of training data 402 based on a model that is already pre-trained, (e.g., pre-trained model 504). Pre-trained (or off-the-shelf) model 504 may include a machine learning model, such as an large language model. Pre-trained model 504 may be trained to perform a generalized task, and may not perform well for a specific task or within a specific domain. Pre-trained model 504 may have been trained with large amounts of training data 502. Pre-trained model 504 may have tens of millions to billions of weights. Training data 502 may include general text data from the Internet and/or other data sources. Pre-trained model 504 is unlikely to be suitable producing responses for synthetic users with different personae. Pre-trained model 504 may perform well when solving generic semantic relationship or question-answering type problems. Pre-trained model 504 may perform poorly in a specific domain, e.g., understanding nuances, patterns, insights about users having different personae and generating responses according to the understanding. It is possible to adapt pre-trained model 504 using transfer learning to develop a model(s) 190 that can be trained to model synthetic users, e.g., synthetic users with different personae. Through transfer learning, pre-trained model 504 may be used as a starting point for developing model(s) 190. Knowledge 560 from pre-trained model 504 can be transferred to model(s) 190. Training data 402 can be provided to model(s), and model(s) 190 can produce outputs 570 from the training data 402. Desired or expected outputs from training data 402 and outputs 570 can be used by update 520 to train model(s) 190. Update 520 can examine an error in the desired or expected outputs from training data 402 and outputs 570 and compute a loss function. Using the loss function, update 520 can update parameters of model(s) 190, e.g., to minimize the loss function. Transfer learning may involve adding artificial neural network layers to existing artificial neural network layers of pre-trained model 504 and updating the parameters in the added artificial neural network layers in training while not updating the parameters of the existing artificial neural network layers. Transfer learning may involve using the pre-trained model 504 as a feature extraction model and adding one or more artificial neural network layers to further process the features extracted by the pre-trained model 504 to build model(s) 190. Training data 402 and outputs 570 can be used by update 520 to train the added artificial neural network layers. Transfer learning may involve update 520 fine-tuning the parameters of one or more existing artificial neural network layers transferred from pre-trained model 504.

### Exemplary Training Data

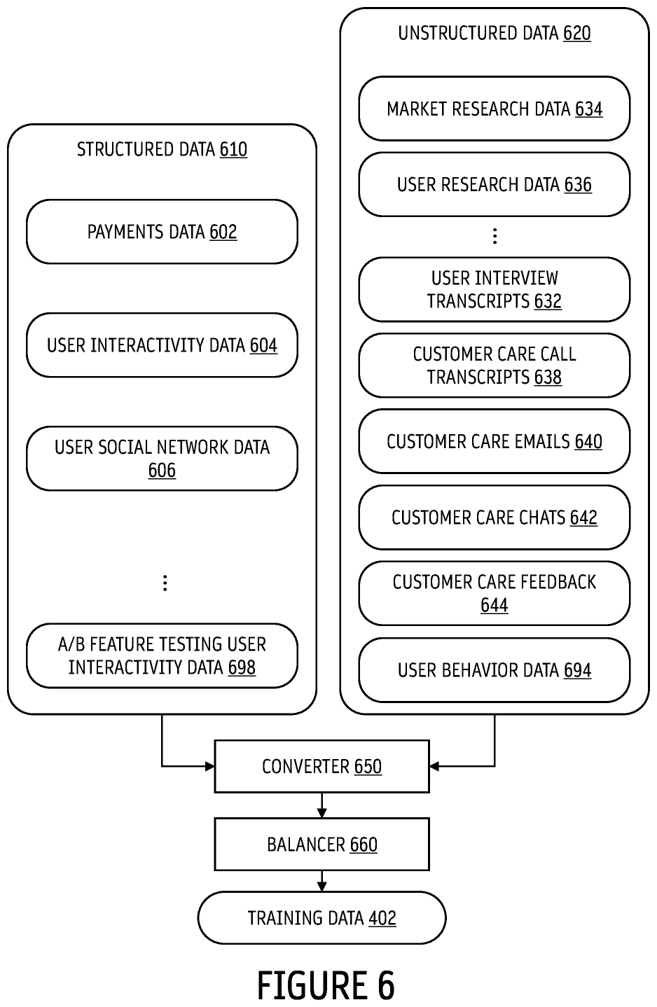

FIG. 6 illustrates transforming user data into training data, according to some embodiments of the disclosure. Performance of model(s) 190 may depend on the quality of training data 402. Model(s) 190 is tasked to model synthetic users, e.g., synthetic users having different personae. Model(s) 190 is tasked to generate output (e.g., feature vectors, feedback, responses, etc.) that is representative of the synthetic users. Suitable training data 402 is preferably representative of signals about synthetic users. Suitable training data 402 is preferably representative of synthetic users across a spectrum of personae. Suitable training data 402 preferably impacts model(s) 190 in a balanced or non-biased way for certain personae. Suitable training data 402 preferably does not cause model(s) 190 to overfit to training data 402 or certain personae. Suitable training data preferably is in a format that link aspects or features about different personae to signals that would inform how synthetic users would respond to inputs such as prompts.

For example, training data 402 may be in a format of an input and an expected or desired output pair. The input may include one or more of:
Features about of (human) user, which may be indicators of a particular persona,
Context (or environment) in which the user is expected to be, and
Question (or stimulus) directed to the user about the context.

The output may include one or more of:
Response (or answer) of the user to the question, and
Labels or annotated features of the input, e.g., highlighting features or dimensions about the input.

Training data 402 may have one or more sources. Training data 402 may come from structured data 610. Structured data 610 may include logs of user activity or interactivity with a system. Structured data 610 may include data collected from a content streaming platform. Training data 402 may come from unstructured data 620. Unstructured data 620 may include text, audio, videos, emails. Unstructured data 620 may include user communication data (e.g., conversations, question and answer, prompt and response, etc.).

Structured data 610 may include payment data 602. Payment data 602 may include logs of data relating to (financial) transactions on a content streaming platform. Data relating to transactions may include information about items which were purchased. Data relating to transactions may include information about credit card transactions, such as details of purchases made using credit cards, credit card number, transaction amount, item purchased, merchant information, whether the credit card was declined, date, time, whether credit limit has been reached, credit card expiration month and year, credit limit, etc. Data relating to transactions may include information about bank transfers, such as transaction amount, sender account number, date, time, etc. Data relating to transactions may include information about digital wallet transactions, such as information about payments made using digital wallet services, date, time, payment amounts, type of digital wallet service, etc. Data relating to transactions may include an indication whether the transaction is set as a recurring transaction. Data relating to transactions may include an indication of how long a recurring transaction is allowed to be repeated until the recurring transaction is paused or cancelled. Data relating to transactions may include an indication of how long until a recurring transaction is restarted after the recurring transaction is paused or cancelled. Data relating to transactions may include a number of recurring transactions for a user. Data relating to transactions may include a total monetary amount of recurring transactions for a user.

Structured data 610 may include user interactivity data 604. User interactivity data 604 may include logs of user session data relating to interactions, behaviors, and/or activity on a content streaming platform. Data that may be tracked or monitored on the content streaming platform as part of user session data may include: session identifier, user identifier, content item impressions (viewed content items), content items that have been focused on, content items that have been previewed (viewed trailer), content items that have been clicked on for more information (viewed description), content items that have been launched (played by user), long watches, short watches, content items that have been skipped or ignored, features that have been utilized or not utilized, user settings, user preferences, language selection, Internet Protocol address, device identifier, software version identifier, streaming hours, purchases, etc. In some cases, user interactivity data 604 may include one or more statistics about individual users that are derived from the logs. In some cases, user interactivity data 604 may include one or more patterns about individual users that are derived from the logs.

Structured data 610 may include user social network data 606. Social network data 606 may include social graphs or networks, and insights that is generated from the social graphs or networks. Social graphs or networks may be generated based on information from a variety of sources, including payment data 602, user interactivity data 604, social media posts, user public profiles, user event attendance information, demographics, content/activity publicly posted by users, relationship information between users, communities that users are in, location of users, etc. Insights may include user demographics, user interests, user behaviors, user engagement, trends, users' radius of influence, user sentiment, user feedback, etc.

Structured data 610 may include A/B feature testing user interactivity data 698. A/B feature testing user interactivity data 698 may include logs of user session data relating to interactions, behaviors, and/or activity on a content streaming platform when users are presented different versions of a feature. Data that may be tracked or monitored on the content streaming platform as part of user session data during A/B feature testing may include: session identifier, user identifier, feature version identifier, content item impressions (viewed content items), content items that have been focused on, content items that have been previewed (viewed trailer), content items that have been clicked on for more information (viewed description), content items that have been launched (played by user), long watches, short watches, content items that have been skipped or ignored, features that have been utilized or not utilized, user settings, user preferences, language selection, Internet Protocol address, device identifier, software version identifier, streaming hours, purchases, etc.

Unstructured data 620 may include market research data 634, and/or user research data 636, e.g., records, transcripts, responses, interactivity logs, behavior logs, analysis results, and/or data gathered through surveys, focus groups, interviews, and online analytics. Market research data 634 may include generalized information about users. Market research data 634 may include persona-specific information about users. User research data 636 may include user-specific information about different users.

Unstructured data 620 may include user communication data, such as user interview transcripts 632, customer care call transcripts 638, customer care emails 640, customer care chats 642, and customer care feedback 644. User communication data may include transcripts of conversations, question and answer, prompt and response, stimulus and reply, etc. User communication data may include data in natural language form. User communication data may include summaries or feature vectors which may be generated by semantic models.

Converter 650 may transform one or more structured data 610 and/or one or more unstructured data 620 into training data 402, e.g., by converting the source(s) of data into a suitable format (e.g., input-output pairs, or prompt-response pairs).

In one example, structured data 610, e.g., payment data 602, may include a data record comprising a user identifier, a payment method, one or more items purchased, and timestamp. Converter 650 may convert the data record into a prompt-response pair, where the prompt may include a description of a persona corresponding to a user having the user identifier, context comprising a description and/or metadata associated with the one or more items purchased, and a question asking if the user would purchase the one or more items, and the response may include a positive/yes to the question.

In another example, structured data 610, e.g., user interactivity data 604, may include a data record comprising a user identifier, a session identifier, a text query used in the session, and a content item launched in the session. Converter 650 may convert the data record into a prompt-response pair, where the prompt may include a description of a persona corresponding to a user having the user identifier, context comprising a description and/or metadata associated with the content item, and a question asking if the user would find the content item relevant to the text query, and the response may include a positive/yes to the question.

In another example, structured data 610, e.g., user interactivity data 604, may include a data record comprising a user identifier, a session identifier, a text query used in the session, and a content item skipped (never launched) in the session. Converter 650 may convert the data record into a prompt-response pair, where the prompt may include a description of a persona corresponding to a user having the user identifier, context comprising a description and/or metadata associated with the content item, and a question asking if the user would find the content item relevant to the text query, and the response may include a negative/no to the question.

In another example, structured data 610, e.g., social network data 606, may include a data record comprising a user identifier, a content item that the user might be interested based on an analysis of social network graph. Converter 650 may convert the data record into a prompt-response pair, where the prompt may include a description of a persona corresponding to a user having the user identifier, context comprising a description and/or metadata associated with the content item, and a question asking if the user would find the content item interesting, and the response may include a maybe yes to the question.

In another example, unstructured data 620, e.g., market research data 634, may include a data record comprising a description of a persona corresponding to a population of users, and one or more content items that the population having the persona would likely purchase. Converter 650 may convert the data record into a prompt-response pair, where the prompt may include a description of the persona, context comprising a description and/or metadata associated with the one or more content items, and a question asking if the user would buy the content item, and the response may include a “maybe yes” to the question.

In another example, unstructured data 620, e.g., user research data 636, may include a data record comprising a description of a persona corresponding to a user, and a content item that the user would decline to purchase due to the price point. Converter 650 may convert the data record into a prompt-response pair, where the prompt may include a description of a persona corresponding to a user having the user identifier, context comprising a description and/or metadata associated with the content item, and a question asking if the user would buy the content item at the price point, and the response may include a “no it is too expensive”.

In another example, unstructured data 620, e.g., user research data 636, may include a data record comprising a user identifier, a question directed to a content item, and a survey/questionnaire answer to the question. The question may include “Did you find the advertisement funny?” The answer may include “Rating: 7 of 10”. Converter 650 may convert the data record into a prompt-response pair, where the prompt may include a description of a persona corresponding to a user having the user identifier, context comprising a description and/or metadata associated with the content item, and the question (“Did you find the advertisement funny?”), and the response may include a the survey/questionnaire answer (“7 out of 10, 10 being the funniest thing I have ever seen”).

In another example, unstructured data 620 may include, e.g., user communication data. User communication data may include a data record comprising a user identifier, a question directed to a content item, and a survey/questionnaire answer to the question. The question may include “What did you think of the scene where the kitten finally found her mom?” The answer may include “Oh I cried!”. Converter 650 may convert the data record into a prompt-response pair, where the prompt may include a description of a persona corresponding to a user having the user identifier, context comprising a description and/or metadata associated with the content item and the scene, and the question (“What did you think of the scene where the kitten finally found her mom?”), and the response may include a the survey/questionnaire answer (“Oh I cried!”).

In another example, unstructured data 620, e.g., user behavior data 694, may include user streaming behavior information about individual users. User behavior data 694 may include summaries about user behavior that are generated from user interactivity data and/or logs. User behavior data 694 may include one or more of: descriptive statistics, inductive statistics, business intelligence, relationships, causal effects, regressions, dependencies, trends, predicted outcomes, etc., about individual users, that can be generated from user interactivity data and/or logs. User behavior data 694 may be generated using a big data platform, based on the user interactivity data and/or logs. User behavior data 694 may be generated using a business intelligence platform, based on the user interactivity data and/or logs. An exemplary record in user behavior data 694 describing user A may include, “Streams 8 hours of Sci-fi movies per week, on paid Sci-fi channel. Mainly on Tuesdays and Fridays”. Another exemplary record in user behavior data 694 describing user B may include, “Watches 4 hours per week of cooking on free, ad-supported cooking channel. Watches 6 hours per week of cartoons on paid Animation Nation Network.” Another exemplary record in user behavior data 694 describing user C may include, “Streamed ‘Alien Bake-Off Battle’ show in 10-minute increments, typically on weekday evenings.”

Balancer 660 may examine distributions of training data associated with different personae and assign weights to different collections of training data associated with different personae to balance or debias training of the model. Weights can be used to weigh reward and/or penalize the model during training as the model parameters are being updated. Assigning weights to certain collections appropriately can alleviate bias, so that certain distributions do not disproportionally impact the model. Balancer 660 may examine distributions of training data associated with different personae and assign weights to different collections of training data associated with signals of different strengths to improve training and performance of the model. If a particular persona has less training data, the weight for the collection of training data may be set higher than another collection of training data that is larger. If a particular persona has more training data, the weight for the collection of training data may be set lower than another collection of training data that is smaller. Some collections of training data can be a stronger indicator or more accurately represent synthetic users, such as payment data may be stronger than user interactivity data. Assigning weights to certain collections appropriately can ensure that the model is not negatively impacted by noisy signals in the training data.

Prompting Synthetic Users to Obtain Feedback from Synthetic Users

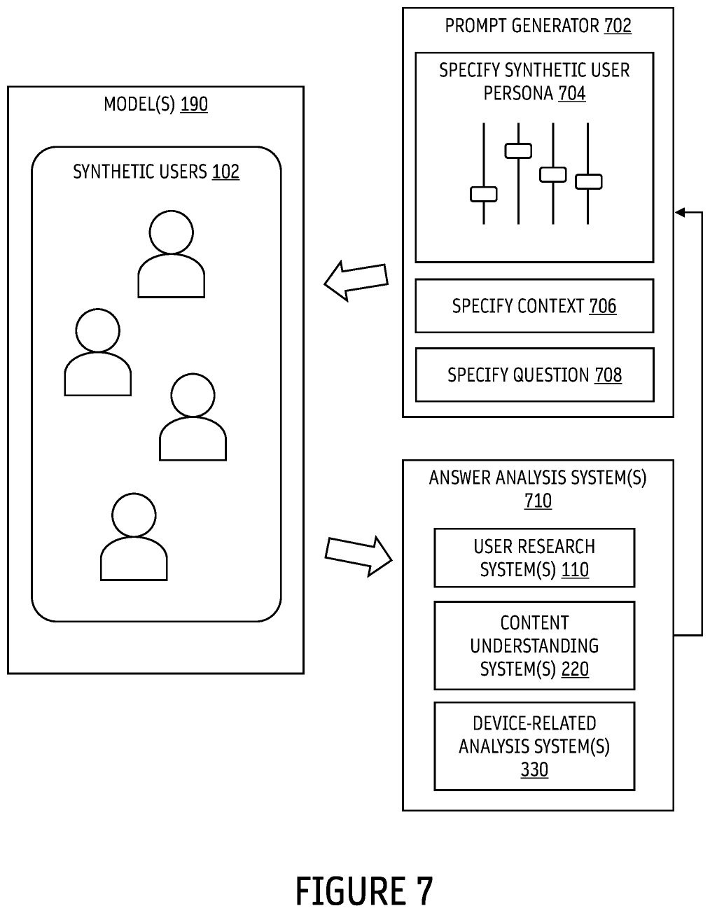

FIG. 7 illustrates inputting prompts and receiving responses from synthetic users, according to some embodiments of the disclosure. Prompt generator 702 may generate inputs that can be provided to model(s) 190. Answer analysis system(s) 710 can collect outputs from model(s) 190 for processing and/or analysis.

Prompt generator 702 may include part 704 that may allow a user, and/or a computer-implemented algorithm/process to specify features and/or characteristics of a persona of synthetic users 102 in model(s) 190. Part 704 may generate a description of a persona capturing the specified features and/or characteristics, which may be used as a part of an input (e.g., prompt) to model(s) 190. Example of a description of a persona may be, “A 35 year old male, living in San Francisco, CA, with a college education, and has no children.”

Prompt generator 702 may include part 706 that may allow a user, and/or a computer-implemented algorithm/process to specify a context that a persona of synthetic users 102 is expected to be in. Part 706 may generate a description of the context, which may be used as a part of an input (e.g., prompt) to model(s) 190. Description of the context may include content and/or a description of content to be considered by synthetic users 102 in model(s) 190. Example of a context may be, “Please read the email: ‘Enjoy more of what you love with a gift from us. As a thank you for being a loyal streamer, we're giving you a $10 credit to watch something new, like a streaming service or movie rental. Claim your offer by May 23, 2023, and we'll automatically apply it to your next eligible purchase. Claim Your Credit click here’”.

Prompt generator 702 may include part 708 that may allow a user, and/or a computer-implemented algorithm/process to specify a question that a persona of synthetic users 102 is expected to answer. Part 706 may generate a question prompting for particular feedback from a persona of synthetic users 102. The question may be used as a part of an input (e.g., prompt) to model(s) 190. The question is expected to be answered by synthetic users 102 in model(s) 190. Example of a question may be, “List what you understand and don't understand.”

In some cases, prompt generator 702 may generate a variety of prompts, e.g., by varying features and/or characteristics of the persona in part 704. In some cases, prompt generator 702 may generate a variety of prompts, e.g., by varying the context in part 706. In some cases, prompt generator 702 may generate a variety of prompts, e.g., by varying the question in part 708.

Answer analysis system(s) 710 may include components to process and/or analyze outputs from model(s) 190 such as parts of user research system(s) 110 of FIG. 1, parts of content understanding system(s) 220 of FIG. 2, and parts of device-related analysis system(s) 330 of FIG. 3.

In some cases, user research system(s) 110 may collect outputs from model(s) 190 generated in response to a variety of prompts generated by prompt generator 702. The outputs may be analyzed by user research system(s) 110. The outputs may represent samples of synthetic users 102, e.g., synthetic users 102 having different personae. In some cases, the analysis may be used to improve the context used in the prompts, e.g., to iteratively improve the context used in the prompts. For example, prompt generator 702 may generate a variety of prompts with different personae to a first version of a screenplay and asking whether synthetic users 102 would watch the movie or not. User research system(s) 110 may analyze the outputs representing reactions of synthetic users 102 having different personae and create a second version of the screen play based on the reactions. Prompt generator 702 may generate a further variety of prompts with different personae to the second version of the screen play and asking whether synthetic users 102 would watch the movie or not.

In some cases, content understanding system(s) 220 may collect outputs from model(s) 190 generated in response to a variety of prompts generated by prompt generator 702. For content understanding system(s) 220, the prompts may include a description of a persona, a context, and a question relating to understanding of the context. The context may include, one or more of: e.g., a description of a content item, metadata of a content item, a description of a scene, extracted text from, an audio clip, closed captions, a description of a shot having a sequence of video frames without changing to a different camera, etc. The outputs may be analyzed by content understanding system(s) 220, representing samples of synthetic users 102, e.g., synthetic users 102 having different personae. In some cases, the outputs may include natural language text responding to the question about the context. In some cases, the outputs may include feature vectors with features extracted from the corresponding inputs (e.g., representing what model(s) 190 extracted or interpreted as salient features in the inputs), or feature vectors having features that encode understanding of the context. The outputs may be used to autonomously annotate content without a human user in the loop. The outputs may be used to summarize shots and/or scenes in a content item. The outputs may be used to extract salient information from shots and/or scenes in a content item. The outputs may be used to describe sentiment and/or reactions to shots and/or scenes in a content item. The outputs may be used to identify natural scene endings and/or scene transitions in a content item. The outputs may be used to identify whether a scene change or change in understanding occurred from one shot to another shot. The outputs may be used to identify pause/break points (e.g., cue points) for injecting/inserting content into the content item. In some embodiments, the outputs may yield information about or targeting specific personae. For example, the annotations or cue points may be specific to a specific persona. In some embodiments, the outputs may yield aggregate or averaged information about a population of synthetic users 102 having a variety of personae. For example, the annotations or cue points may be generic or suitable for most users.

In some cases, device-related analysis system(s) 330 may collect outputs from model(s) 190 generated in response to a variety of prompts generated by prompt generator 702. For device-related analysis system(s) 330, the prompts may include a description of a persona, a context, and a question relating to understanding of the context. The context may include, one or more of: e.g., a description of a device, a description of user preferences, a description of user settings, a description of related device(s), etc. The outputs may be analyzed by device-related analysis system(s) 330, representing samples of synthetic users 102, e.g., synthetic users 102 having different personae. The outputs may be used to recommend user preferences and/or user settings to users having a particular persona. The outputs may be used to recommend related product(s) for purchase to users having a particular persona.

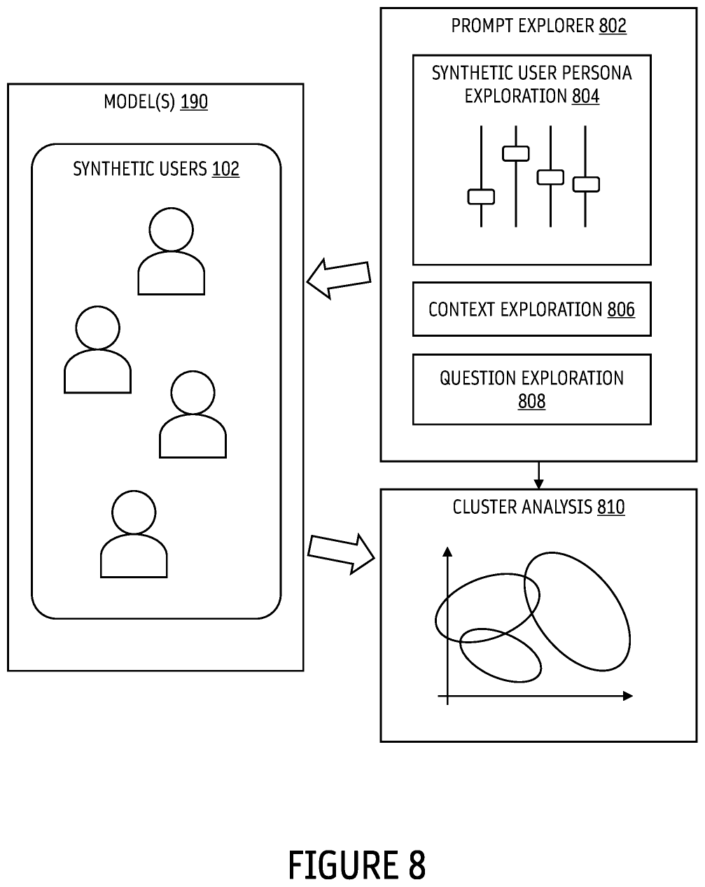

FIG. 8 illustrates cluster analysis 810 based on feedback from synthetic users 102, according to some embodiments of the disclosure. Prompt explorer 802 may be used to generate a variety of prompts that can explore synthetic users 102 and the outputs (e.g., responses from synthetic users 102) to find out how synthetic users 102 may be clustered or grouped. Exploring the outputs may enable discovery of whether a subset of synthetic users 102 having particular features and/or characteristics and a different subset of synthetic users 102 having different features and/or characteristics belong to the same group/cluster, or not. Synthetic users 102 may be grouped or clustered by cluster analysis 810 based on the similarity of responses from synthetic users 102. The outputs from model(s) 190 may represent different or similar feedback and/or responses from synthetic users 102, e.g., synthetic users 102 with different personae.

Prompt explorer 802 may include part 804 that may allow a user, and/or a computer-implemented algorithm/process to vary or specify different combinations of persona features and/or characteristics of synthetic users 102 in model(s) 190. Part 804 may generate varied descriptions of different persona capturing different combinations of features and/or characteristics, which may be used as in inputs (e.g., prompts) to model(s) 190. Example of a description of a persona may be, “A 65-year-old female, living in New York, NY, watches Sci-fi often, spends 12 hours each week on a content streaming platform, and has six children.”

Prompt explorer 802 may include part 806 that may allow a user, and/or a computer-implemented algorithm/process to specify one or more contexts that a persona of synthetic users 102 is expected to be in. In some cases, cluster analysis 810 may analyze how synthetic users 102 may respond to a variety of contexts to determine groups/clusters of synthetic users 102. Part 806 may generate a description of the context, which may be used as a part of an input (e.g., prompt) to model(s) 190. Description of the context may include content and/or a description of content to be considered by synthetic users 102 in model(s) 190. Example of a context may be, “You have two lighting devices in your shopping cart. You have entered your credit card information and just clicked ‘Check Out’. You are asked whether you would like to also add on device hub manager for $49.99 (a discount of 50%). You also just earned free shipping. Your total payment is updated to $265.45. You are told that 85% of users who have two or more lighting devices find it helpful to have a device hub manager. You can click ‘Yes!’ to check out with the device hub manager included. You can click ‘No Thanks’ to check out without the device hub manager.”

Prompt explorer 802 may include part 808 that may allow a user, and/or a computer-implemented algorithm/process to specify one or more questions that a persona of synthetic users 102 is expected to answer. In some cases, cluster analysis 810 may analyze how synthetic users 102 may respond to a variety of questions to one or more contexts to determine groups/clusters of synthetic users 102. Part 806 may generate a question prompting for particular feedback from a persona of synthetic users 102. The question may be used as a part of an input (e.g., prompt) to model(s) 190. The question is expected to be answered by synthetic users 102 in model(s) 190. In some cases, the question may include a request to rank or indicate preference between two or more options. Example of a question may be, “Would you prefer a bundle of 3 subscriptions for $12 dollars a month or a bundle of 2 subscriptions for $10 dollars a month?”

In some cases, prompt explorer 802 may generate a variety of prompts, e.g., by varying features and/or characteristics of the persona in part 804. In some cases, prompt explorer 802 may generate a variety of prompts, e.g., by varying the context in part 806. In some cases, prompt explorer 802 may generate a variety of prompts, e.g., by varying the question in part 808.

Cluster analysis 810 may include components to process and/or analyze outputs from model(s) 190. Cluster analysis 810 may be used to explore which clusters/groups may respond differently to a particular context and question. Cluster analysis 810 may be used to explore generally which clusters/groups may respond similarly within a cluster/group. In some cases, the outputs may include natural language text responding to the question about the context. Cluster analysis 810 may analyze the outputs for similarities and dissimilarities. In some cases, the outputs may include feature vectors with features extracted from the corresponding inputs (e.g., representing what model(s) 190 extracted or interpreted as salient features in the inputs), or feature vectors having features that encode understanding of the context. Cluster analysis 810 may be performed on a collection of feature vectors (e.g., by finding distances between pairs of feature vectors and locating groups/clusters in multi-dimensional space) to find different groups/clusters of synthetic users 102.

### Exemplary User Data for Building Synthetic User Memories

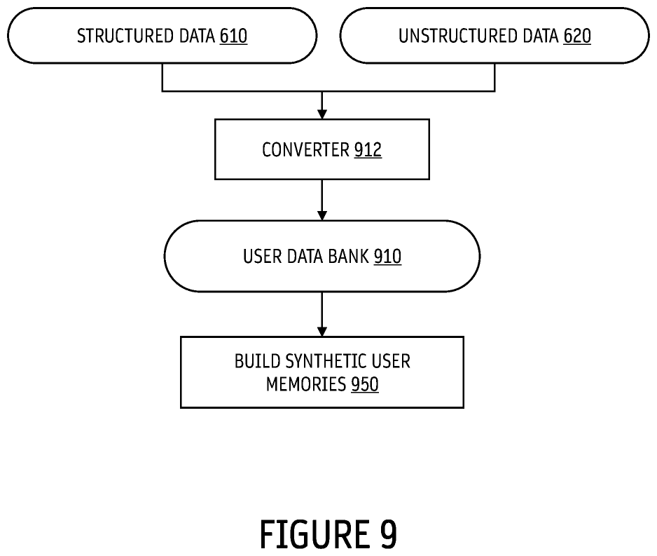

A (pre-trained, generic) model can be prompted to respond differently to different contextual information about different users using prompt chaining. Different prompt chains corresponding to different synthetic users can be created from different synthetic user memories. FIG. 9 illustrates user data used to build synthetic user memories, according to some embodiments of the disclosure. User data, e.g., in the form of data entries and/or natural language entries, may be stored in user data bank 910, which may be used later to build synthetic user memories in 950.

Synthetic user memories can capture different synthetic user experiences. Synthetic user memories can offer insights about the user and/or the behavior of the user. Synthetic user memories may be initialized using data about real human users. Data about real human users may include examples illustrated with structured data 610. Data about real human users may include examples illustrated with unstructured data 620. An example of data about real human users may include historical data gathered from focus group research (e.g., survey questions and survey answers, user demographic data, interview transcripts, etc.). Another example of data about real human users may include user interactivity data logged during past feature testing (e.g., A/B feature testing or other types of experiments). Another example of data about real human users may include user interactivity data logged while human users are using a content streaming platform (e.g., while users are using a recommendation engine to search for content). Another example of data about real human users may include user support chat logs or conversations with users. Another example of data about real human users may include payment and/or purchase history. Another example of data about real human users may include user profile data produced by business intelligence systems and/or big data systems.

Preferably, the model is a large language model, which takes natural language inputs and may generate natural language outputs. Accordingly, structured data 610 may be converted into natural language entries that represent the structured data 610. Unstructured data 620 may be converted to natural language entries that represent the unstructured data 620. The natural language entries can be stored in user data bank 910.

In some embodiments, the data about real human users may include demographic information about the first user, one or more survey questions, and one or more survey answers. Converter 912 may convert the demographic information into natural language entries, e.g., sentences and/or statements formed from the demographic information. Example: “Billy F. is a college student living in a dorm and plays video games 20 hours a week. Billy's is 17 years old.” Converter 912 may convert the one or more survey questions and the one or more survey answers into natural language entries, e.g., sentences and/or statements about a user. Example: “Billy F. would pay $2 dollars a month extra for Animation Nation Network.”

In some embodiments, the data about real human users may include user interactivity data of the first user on the content streaming platform logged during an experiment. Converter 912 may convert the user interactivity data into natural language entries, e.g., sentences that describe the user interactivity data. In some embodiments, converter 912 may translate user interactivity data into natural language descriptions of the user interactivity data. In some embodiments, converter 912 may translate user interactivity data comprising one or more user interface workflow steps into natural language descriptions of the one or more user interface workflow steps (e.g., describing what a user clicked on, what was shown to the user, what a user provided as input into the user interface, what the user did on the user interface). In some embodiments, converter 912 may translate user interactivity data comprising one or more subscription workflow steps into natural language descriptions of the one or more subscription workflow steps (e.g., describing what was shown to the user, what the user subscribed to, how much the user paid for the subscription, how long the user kept the subscription, when the user cancelled the subscription, when the user upgraded the subscription, etc.). Example: “Billy F. launched ‘Cooking with Space Aliens’ after searching for ‘extraterrestrial adventure shows’.” Example: “Billy F. searched for ‘extraterrestrial adventure shows’. After skipping over ‘Glamping on the Moon’, and ‘Surviving on Venus’, Billy F. launched ‘Cooking with Space Aliens’” Example: “Billy F. cancelled a subscription to Animation Nation Network.” Example: “Billy F. subscribed to Animation Nation Network at a promotional price of $2.99 a month for the first three months. Billy F. used the subscription to watch shows for 12.5 hours. Billy F. cancelled the subscription a month after subscribing.” Example: “Billy F. binged watched ‘Cooking with Space Aliens’ for 7.5 hours.”

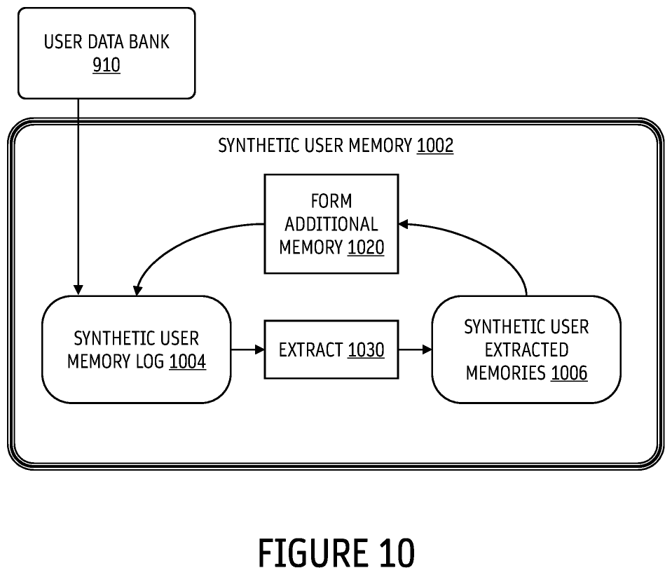

Natural language entries in user data bank 910 may be used to build synthetic user memories in 950. Additional details on building synthetic user memories are described with FIGS. 10-11, and 16-17.

### Building Synthetic User Memories

FIG. 10 illustrates creating synthetic user memory, according to some embodiments of the disclosure. Synthetic user memory 1002 may correspond to a synthetic user. Relevant entries from user data bank 910 may be used to form synthetic user memory 1002. The entries, e.g., user data corresponding to a user or a persona, may be stored in synthetic user memory log 1004.

In some embodiments, first user data corresponding to a first user of a content streaming platform may be determined. First user data may be obtained from user data bank 910. Optionally, first user data may be converted into first natural language log entries. First user data may be stored as first natural language log entries of a first memory log (e.g., illustrated as synthetic user memory log 1004). The first memory log may be used to capture experiences and/or actions of the first user and higher-level memories generated for a first user.

An extraction function, e.g., in extract 1030, may be used to extract a first subset of first natural language log entries from the first memory log (e.g., illustrated as synthetic user memory log 1004). The first subset of the first natural language log entries may be presented as synthetic user extracted memories 1006. There may be a voluminous number of entries in synthetic user memory log 1004. An extraction function may serve to extract entries that are suitable for forming one or more additional memories, e.g., in form additional memory 1020, to improve synthetic user memory 1002.

In some embodiments, the extraction function may include a scoring function that scores the individual entries in synthetic user memory log 1004. The extraction function may select a top K number of entries which have the highest scores to be in the first subset of the first natural language log entries (e.g., illustrated as synthetic user extracted memories 1006). The scoring function may score (individual) first natural language log entries in the first memory log (e.g., illustrated as synthetic user memory log 1004). The scoring function may be based on freshness of an entry. Freshness may be defined based on how recent the entry was added in the synthetic user memory log 1004. Freshness of an entry may decay according to a decay rate in the synthetic user memory log 1004. Some decay rates may differ depending on the entry, e.g., type of entry, source of the entry, saliency of the entry, etc. The scoring function may be based on the accuracy of an entry. In some cases, the entry is generated by a model. The entry may or may not accurately reflect the first user data about the first user. The accuracy of the entry may be lower when the entry does not correspond with the first user data. The accuracy of the entry may be higher when the entry does correspond with the first user data. The accuracy of an entry may be measured based on an evaluation of a response generated by the model against the first user data. In some cases, the scoring function may be based on one or more other factors such as saliency, relevance, etc. The factors may be measured based on whether the model has identified an entry as being used in making a decision or performing an action.

In some embodiments, the extraction function may include a selection function that selects one or more responses generated by the model to be presented as synthetic user extracted memories 1006. The one or more responses may be included as part of the first subset of the first natural language log entries (e.g., illustrated as synthetic user extracted memories 1006). The one or more responses may enable a prompt chain to be created using the one or more responses as part of an input prompt to the model. In some cases, a prompt chain may include only responses generated by the model. In some cases, a prompt chain may include one or more responses generated by the model and one or more (raw) natural language log entries of synthetic user memory log 1004 retrieved from user data bank 910.

In some embodiments, the extraction function may include a selection function that selects one or more clusters or categories of natural language log entries in synthetic user memory log 1004 to be presented as synthetic user extracted memories 1006. Entries in synthetic user memory log 1004 may be clustered so that similar entries are grouped in clusters. Entries in synthetic user memory log 1004 may be associated with different categories, e.g., raw user interactivity data, higher-level summary generated by the model, reasoning generated by the model, ranking generated by the model, action generated by the model, score generated by the model, etc.

Form additional memory 1020 may prompt a model (e.g., a large language model) using the first subset of the first natural language log entries (e.g., synthetic user extracted memories 1006). Form additional memory 1020 may prompt a model to summarize the synthetic user extracted memories 1006. Form additional memory 1020 may prompt a model to identify what was most interesting or important about the synthetic user extracted memories 1006. Form additional memory 1020 may prompt a model to provide a reasoning that explains the synthetic user extracted memories 1006. Form additional memory 1020 may prompt a model to generate a reaction to the synthetic user extracted memories 1006. Form additional memory 1020 may prompt a model to generate a action that follows the synthetic user extracted memories 1006. Form additional memory 1020 may receive a first generated response in response to prompting the model using the first subset or the synthetic user extracted memories 1006. Form additional memory 1020 may incorporate the first generated response, e.g., as a new memory or additional memory log entry, into the first memory log (e.g., synthetic user memory log 1004).

In some cases, form additional memory 1020 may input a question and the first subset of the first natural language log entries (e.g., synthetic user extracted memories 1006) to the model to generate an opinion about the first subset of the first natural language log entries.

In some cases, form additional memory 1020 may input a question and the first subset of the first natural language log entries to the model to generate a statement about the first subset of the first natural language log entries and a reasoning behind the statement. For example, form additional memory 1020 may present a description of a user liking a set of shows and a question to the model to summarize in 20 words why the user enjoyed watching these shows.

In some cases, after incorporating the first generated response, extract 1030 may extract a second subset of the first natural language log entries from the first memory log using the extraction function. Extract 1030 may extract a different subset of entries using the revised first memory log, and output synthetic user extracted memories 1006. Form additional memory 1020 may form another new memory or additional memory log entry based on the second subset of the first natural language log entries, by prompting the model using the second subset of the first natural language log entries. Form additional memory 1020 may receive a second generated response in response to the prompting using the second subset. Form additional memory 1020 may incorporate the second response into the first memory log (e.g., into synthetic user memory log 1004). The process of extraction in extract 1030 and forming additional memories in form additional memory 1020 may repeat and iteratively build up synthetic user memory 1002 and synthetic user extracted memories 1006 to better emulate/simulate the first user.

By iteratively prompting the model to generate responses and incorporating the responses in synthetic user extracted memories 1006, a prompt chain built using the synthetic user extracted memories 1006 can force the model to respond to the prompt chain within a certain vectorial space that corresponds to the user or persona. Phrased differently, the model may respond to the prompt chain by generating responses to the prompt chain that are most likely or probable for the particular user or persona.

The process illustrated for building the synthetic user memory for the first user may be performed for one or more other users, e.g., a second user. Second user data corresponding to a second user of the content streaming platform can be determined or obtained from user data bank 910. The second user data may optionally be converted into second natural language log entries, and stored in a second memory log (separate from the first memory log). Using one or more second natural language log entries (e.g., extracted using an extraction function), the model may generate one or more third responses to form one or more additional memories. The one or more third responses may be incorporated into the second memory log.

Performing the process for different users to build different synthetic user memories may result in capturing different representations and reactions of various users. Different prompt chains built from the different synthetic user memories may cause the model to operate and respond to the different prompt chains within different vectorial spaces. The model may be prompted to respond to the different prompt chains by generating responses that are most likely or probable for the different users or personae. The entries in synthetic user memories and responses generated by the model can be analyzed to better understand the behavior of various users and behavior of a population of users. In some cases, a test question can be input as a prompt to the model along with extracted natural language log entries of a memory log (e.g., thereby forming a prompt chain) to solicit a response from the model that is based on the contextual information encoded in the prompt chain. The same test question can be input as part of different prompt chains using different extracted natural language log entries of different memory logs. The responses to the test question can be collected and analyzed, e.g., to examine differences and/or similarities of responses of different users. For example, (1) a response generated by the model in response to a test question and one or more first natural language log entries of the first memory log, and (2) a response generated by the model in response to the test question and one or more second natural language log entries of the second memory log may be collected and analyzed.

### Evaluating the Model's Response to a Prompt Chain and Modifying the Memory Log Accordingly

Building a prompt chain is an iterative process of prompting a model to generate responses to the prompt chain. The final, resulting prompt chain can include sufficient context or memory about a particular user or persona using generated responses from the model, so that the model may respond in a vectorial space that accurately represents the particular user or persona. It is not trivial to evaluate whether a prompt chain or synthetic user memory accurately captures the user and the user's behaviors, and whether the model would generate responses that represent an accurate prediction of the user's actions or reactions. In some cases, user data about users, e.g., users of a content streaming platform, may have a priori knowledge (e.g., ground truth information) about the user's responses to certain prompts. The user data may already include one or more prompt and response pairs, which can be used to test whether the prompt chain is soliciting a response that matches an expected response. The result of the evaluation can be used to modify the prompt chain that is generated and/or the synthetic user memory being used to generate the prompt chain. Repeated evaluation and modification to tokens (e.g., words) being used in a prompt chain can help refine the prompt chain. Repeated evaluation of responses generated in response to different prompt chains can emulate a chain of thought process or a conversation chain with the model. The chain of thought process or the conversation chain can iteratively correct and/or remove incorrect responses. The chain of thought process or the conversation chain can reiterate and/or reemphasize the correct responses from the model. Iterative refining the prompt chain can help push the model to respond in a vectorial space that more accurately represents a particular user or persona.

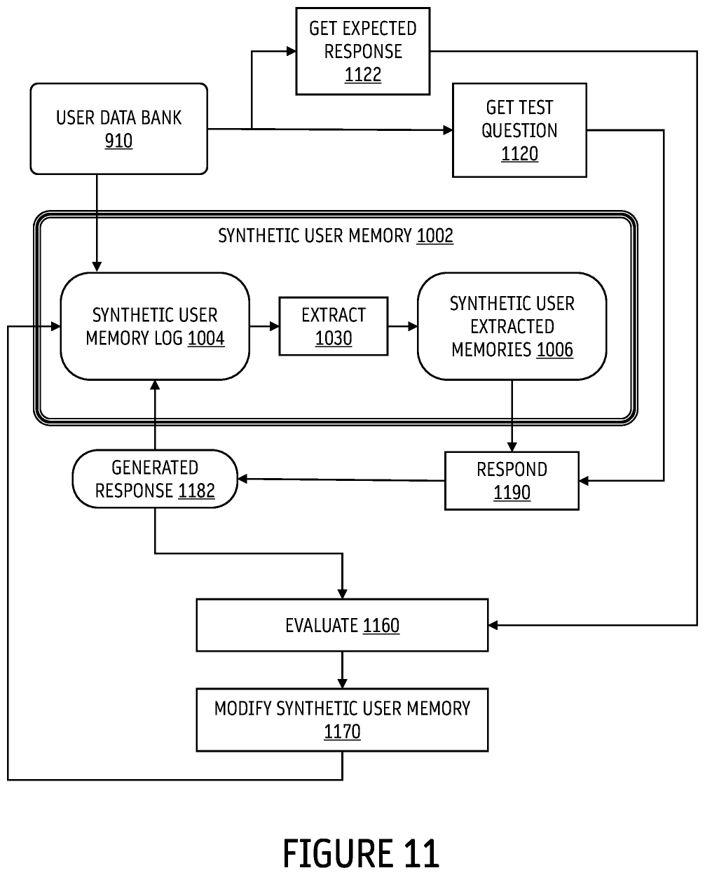

FIG. 11 illustrates evaluation of a generated response and modification of synthetic user memory, according to some embodiments of the disclosure. Get test question 1120 may determine a first question from the user data. The user data may correspond to a user of a content streaming platform. The first question may come from user data bank 910. The first question may come from synthetic user memory log 1004. Get expected response 1122 may determine a first expected response to the first question. The first expected response may come from user data bank 910. The first expected response may come from synthetic user memory log 1004.

In some embodiments, the first question may include a survey question previously presented to the user. In some cases, the first expected response may include a survey response to the survey question provided by the user.

In some embodiments, the first question may include user interactivity data corresponding to a first time frame. The first expected response may include user interactivity data corresponding to a second time frame. The second time frame may be after the first time frame. The first expected response may represent a causal action being performed in response to the first question representing events that may have led to the casual action.

Similar to the extraction process described with FIG. 10, a first subset of natural language log entries in the synthetic user memory log 1004 may be extracted by extract 1030 to form synthetic user extracted memories 1006. The first subset of natural language log entries and the first question may be input as a prompt to a model (e.g., a large language model). The first subset of natural language log entries and the first question together may test the prompt chain that is formed using the first subset of natural language log entries. The first subset of natural language log entries and the first question together may test whether the model would respond as expected.

In respond 1190, the model may output a first generated response in response to the inputting of the first subset of natural language log entries and the first question into the model. In respond 1190, the model may produce a first generated response 1182. In some embodiments, the first generated response 1182 may be incorporated into the synthetic user memory log 1004, e.g., as a new memory or additional memory log entry.

In evaluate 1160, the first generated response 1182 may be evaluated against the first expected response obtained from get expected response 1122.

In modify synthetic user memory 1170, the synthetic user memory log 1004 may be modified based on the evaluating in evaluate 1160.

In evaluate 1160, accuracy of the first generated response may be determined based on the first expected response. Accuracy may be determined, e.g., based on similarity or dissimilarity of the first generated response and the first expected response. The first generated response and the first expected response may be provided as inputs to a model to obtain feature vectors that correspond to the first generated response and the first expected response. A dot product of the feature vectors having a low value may indicate that the first generated response and the first expected response are similar. A dot product of the feature vectors having a high value may indicate that the first generated response and the first expected response are dissimilar. The dot product of the feature vectors may be compared against a threshold to determine whether the first generated response and the first expected response are similar or not.

In modify synthetic user memory 1170, accuracy score of the first response in the memory log (e.g., synthetic user memory log 1104) may be set based on the evaluating. The accuracy score may be used in subsequent extraction of one or more subsets of natural language log entries (e.g., in extract 1030) for prompting the model. The accuracy score may be set to a low value (e.g., 0) if the result in evaluate 1160 indicates that the first response is not accurate. The accuracy score may be set to a high value (e.g., 100) if the result in evaluate 1160 indicates that the first response is accurate. The accuracy score may be set based on the dot product of the feature vectors determined in evaluate 1160. The accuracy score may have discrete values. The accuracy score may have continuous values. The accuracy score may be normalized.

In modify synthetic user memory 1170, the first response may be removed from the memory log (e.g., synthetic user memory log 1104).

In modify synthetic user memory 1170, the first response, the first question, and the first expected response may be removed from the memory log (e.g., synthetic user memory log 1104). In some cases, additional entries may be removed from the memory log. In some cases, at least a portion (e.g., at least one or more log entries) of the memory log may be reset or erased based on the evaluating in evaluate 1160.

After the synthetic user memory 1002 is modified based on the evaluating in evaluate 1160, the model may be prompted with a different prompt chain. Get test question 1120 may determine a second question from the user data. The second question may come from user data bank 910. The second question may come from synthetic user memory log 1004. Get expected response 1122 may determine a second expected response to the second question. The second expected response may come from user data bank 910. The second expected response may come from synthetic user memory log 1004. In respond 1190, a second subset of natural language log entries of the memory log and the second question may be input into the model. In respond 1190, the model may output a second generated response from the model in response to the inputting. In some cases, the second generated response may be incorporated into the memory log (e.g., synthetic user memory log 1004). In evaluate 1160, the second generated response may be evaluated against the second expected response. In modify synthetic user memory 1170, the memory log (e.g., synthetic user memory log 1004) may be modified based on the evaluating in evaluate 1160.

In some embodiments, evaluate 1160 may determine that the first generated response may not be entirely accurate, or may be partially accurate. Modify synthetic user memory 1170 may generate a modified version of the first generated response and incorporating the modified version of the first generated response into synthetic user memory log 1004. The modified version of the first generated response may omit a portion of the first generated response that is inaccurate and has a portion of the first generated response that is accurate. This modification to the first generated response can mean that at least some tokens of the first generated response can be used in a prompt chain while omitting certain tokens of the first generated response. The prompt chain, using the accurate tokens, can cause the model to get closer to the correct vectorial space that more accurately represents the user or persona.

In some embodiments, evaluate 1160 may determine that the first generated response may be at least partially inaccurate. Modify synthetic user memory 1170 may generate a modified version of the first response and incorporating the modified version of the first response into synthetic user memory log 1004. The modified version of the first response may include a correction to the portion of the first response that is inaccurate. For example, the modified version of the first response may include, e.g., “Billy F actually finds ‘Time Traveling with Alien Chefs’ repulsive, unrelatable, and unappetizing. Billy F would prefer to watch cooking shows such as ‘Cooking with Cat Helpers’ and ‘Healthy Stress Baking’”. This modification to the first generated response can mean that at least some tokens of the first generated response can be used in a prompt chain while correcting certain tokens of the first generated response. The prompt chain, using the accurate tokens and corrected tokens, can cause the model to get closer to the correct vectorial space that more accurately represents the user or persona, and farther away from the incorrect vectorial space that does not accurately represent the user or persona.

Performing and/or Completing an Experiment Using Synthetic Users

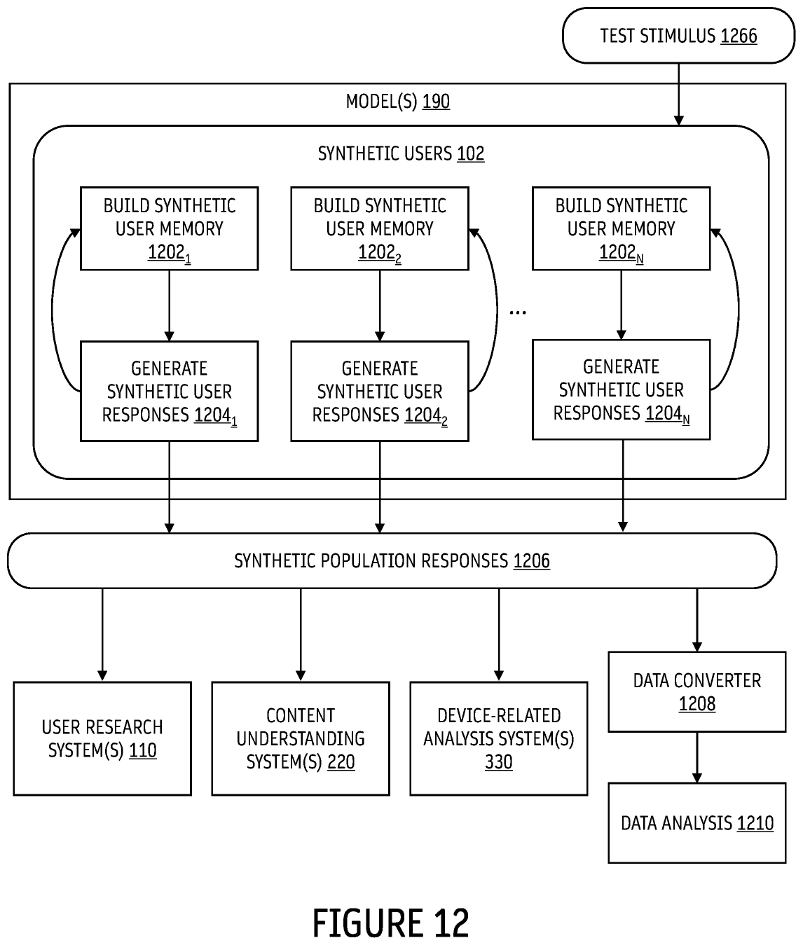

FIG. 12 illustrates obtaining synthetic population responses and analyzing thereof, according to some embodiments of the disclosure. Using processes illustrated in FIGS. 10-11, a population of synthetic users 102 may be modeled in model(s) 190. Build synthetic user memory 1202₁, . . . and build synthetic user memory 1202_{N}, may be implemented to build user memories corresponding to N different users. Model(s) 190 may be prompted using corresponding user memories or prompt chains made from the user memories to generate synthetic population responses 1206, in generate synthetic user responses 1204₁, . . . and generate synthetic population responses 1 206, in generate synthetic user responses 1204_{N}. Generated responses may be used as subsequent input prompts to model(s) 190 to perform prompt chaining. Generate synthetic user responses 1204ᵢ may be combined with or performed as a part of build synthetic user memory 1202ᵢ.

In some embodiments, the synthetic population responses 1206 may include simulated responses from a population of synthetic users. The synthetic population responses 1206 may include simulated responses from a population of synthetic users in response to one or more pre-determined test questions and respective prompt chains that have been created for the synthetic users. In some cases, the pre-determined test question includes a description of a user workflow, and a request to the synthetic user to complete the workflow. In some cases, the pre-determined test question includes a description of multi-modal information presented to the user (e.g., involving text, images, audio, user interface elements, etc.), and a request to the synthetic user to react to the description.

Systems such as user research system(s) 110, content understanding system(s) 220, and device-related analysis system(s) 330 may receive the synthetic population responses 1206 and produce analysis of the synthetic population responses 1206. In some cases, synthetic population responses 1206 may be provided to a data converter 1208 to translate the synthetic population responses 1206 from natural language log entries produced by the model into quantitative information. Data converter 1208 may include natural language processing to extract quantitative information from synthetic population responses 1206. The quantitative information may be provided to data analysis 1210 for statistical data analysis of the simulated responses from a population of synthetic users, e.g., for purposes of producing findings and/or validating a hypothesis of an experiment.

In some embodiments, synthetic population responses 1206 may be generated in response to a pre-determined question having a fixed set of possible answers. Synthetic population responses 1206 may include a selection or identification of an answer in the fixed set of possible answers. Data converter 1208 may extract the selected or identified answer from synthetic population responses 1206 and store the extracted answers as a dataset in a database. Data analysis 1210 may analyze the dataset to extract statistics, such as cumulative frequency of the answers, and frequency of the answers given a certain characteristic of the users or personae.

In some embodiments, synthetic population responses 1206 may be generated in response to a pre-determined question to rank or order a fixed set of items. Synthetic population responses 1206 may include a ranked list of the items. Data converter 1208 may extract the ranking order from the synthetic population responses 1206 and store the extracted ranking order as a dataset in a database. Data analysis 1210 may analyze the dataset to extract statistics, e.g., frequency of the answers, and frequency of the answers given a certain characteristic of the users or personae.

In some embodiments, synthetic population responses 1206 may be generated in response to a pre-determined question to give a rating to an item. Synthetic population responses 1206 may include a rating, e.g., a number on a scale from 1 to 10. Data converter 1208 may extract the ratings from the synthetic population responses 1206 and store the extracted ratings as a dataset in a database. Data analysis 1210 may analyze the dataset to extract statistics, e.g., average/mode/median of the ratings, histogram of the ratings, standard deviation of the ratings, and average/mode/median of the ratings given a certain characteristic of the users or personae.

In some embodiments, synthetic user memories of N different users may be built using user interactivity data logged during an experiment performed on N different real human users, e.g., an A/B feature test, or A/B feature test that is not yet completed (or cut short). N different human users may be separated into multiple groups exposed to different features. Using the processes described in FIGS. 10-11, it is possible to simulate and create N different synthetic user memories for the N different real human users based on user interactivity data logged for these N different real human users. Subsets of log entries in the memory log may be used in a prompt, e.g., a prompt chain, to obtain generated responses from a model. The generated responses may include predicted actions based on the contextual information presented in the prompt. The generated responses can represent new memories or actions. The generated responses may be generated and added to the memory log repeatedly to simulate the execution or progression of the rest of the experiment. The resulting memory log may include actual logged user interactivity data and predicted actions.

A first synthetic user memory, or first synthetic user memory log can be built using first user interactivity data corresponding to a first user (e.g., a first user of a content streaming platform) that is logged during an experiment. The first user may belong to a first group of users exposed to a first feature of the content streaming platform. Optionally, the first user interactivity data may be translated into first natural language log entries and stored in the first synthetic user memory log. The first synthetic user memory log may be built by, e.g., build synthetic user memory 1202₁. A first subset of the first natural language log entries in the first synthetic user memory log and a first request to generate a first response representing a first predicted action of the first user based on the first subset of the first natural language log entries may be input into a model. The generated first response may be added into the first synthetic user memory log. Inputting and adding may be performed by, e.g., generating synthetic user responses 1204₁.

A second synthetic user memory, or second synthetic user memory log can be built using second user interactivity data corresponding to a second user (e.g., a second user of a content streaming platform) that is logged during the same experiment. The second user may belong to a second group of users exposed to a second feature of the content streaming platform (second feature being different from the first feature). Optionally, the second user interactivity data may be translated into second natural language log entries and stored in the second synthetic user memory log. The second synthetic user memory log may be built by, e.g., build synthetic user memory 12022. A second subset of the second natural language log entries in the second synthetic user memory log and a second request to generate a second response representing a second predicted action of the second user based on the second subset of the first natural language log entries may be input into the model. The generated second response may be added into the second synthetic user memory log. Inputting and adding may be performed by, e.g., generating synthetic user responses 12042.

Data analysis 1202 may analyze the first synthetic user memory log and the second synthetic user memory log to determine effects of the first feature and the second feature.

In some embodiments, data converter 1208 may convert one or more natural language log entries in the first synthetic user memory log and/or synthetic population responses 1206 corresponding to the first user into a first quantitative metric about the first feature. Data converter 1208 may convert one or more natural language log entries in the second synthetic user memory log and/or synthetic population responses 1206 corresponding to the second user into a second quantitative metric about the second feature.

In some embodiments, as part of the building of a synthetic user memory log, the model may be prompted to output quantitative metrics. For example, building the first synthetic user memory log may include inputting, into the model, a third subset of the first natural language log entries of the first synthetic user memory log and a question to generate a first quantitative metric about the third subset of the first natural language log entries. The generated first quantitative metric may be added into the first synthetic user memory log. building the second synthetic user memory log may include inputting, into the model, a fourth subset of the second natural language log entries of the second synthetic user memory log and a question to generate a second quantitative metric about the fourth subset of the second natural language log entries. The generated second quantitative metric may be added into the second synthetic user memory log.

In some cases, in addition to a request to generate a predicted action, the request may include one or additional instruction(s) to prompt the model to form higher-level abstract memories and reasoning about the predicted action and/or past user interactivity data. The higher-level abstract memories and/or reasoning may give explainable insights about the predicted actions and/or behavior of users. For example, the first request may further include a first instruction to generate a first reasoning for the first predicted action. The second request may further include a second instruction to generate a second reasoning for the second predicted action. In another example, the first request may further include a third instruction to identify one or more first natural language log entries in the first subset that led to the first predicted action. The second request may further include a fourth instruction to identify one or more second natural language log entries in the second subset that led to the second predicted action.

In some cases, to ensure the model generates responses consistently, the model may be prompted to summarize the factors or considerations the synthetic user may take into account when performing a given action. The model may output a set of factors or considerations in a response. Then, the model may be prompted to generate a predicted action for the synthetic user and a reasoning behind the predicted action in view of the factors or considerations that the model produced in the earlier response. The model may generate a response having a predicted action that would be consistent with the factors or considerations that the model produced in the earlier response.

In some cases, the simulation of the experiment using synthetic users 102 may be halted based on one or more conditions being met. The simulation is halted or stopped when no further prompting is done to the model to generate new memories. One condition may include determining that a difference in the effects of the first feature and the second feature is statistically significant based on the first synthetic user memory, the second synthetic user memory, and further synthetic user memories. Another condition may include determining that the first synthetic user memory and the second synthetic user memory have reached a certain size, which may indicate that the simulation has been executed long enough.

In some cases, a test stimulus 1266 may be used to obtain different responses from the synthetic users 102. A test stimulus 1266 may include a description of an event or observation. A test stimulus 1266 may be a constructed/artificial natural language memory log entry. To obtain a response to the test stimulus 1266 representing a reaction of the first user, a fourth subset of the first natural language log entries of the first synthetic user memory log, and a description of a test stimulus may be input into the model. The model may generate a third response of the first user based on the fourth subset of the first natural language log entries and the test stimulus. The generated third response can be added into the first synthetic user memory log. The process may be applied similarly to obtain a response to the test stimulus 1266 representing a reaction of the second user using the second synthetic user memory log.

### Exemplary Methods for Training Models

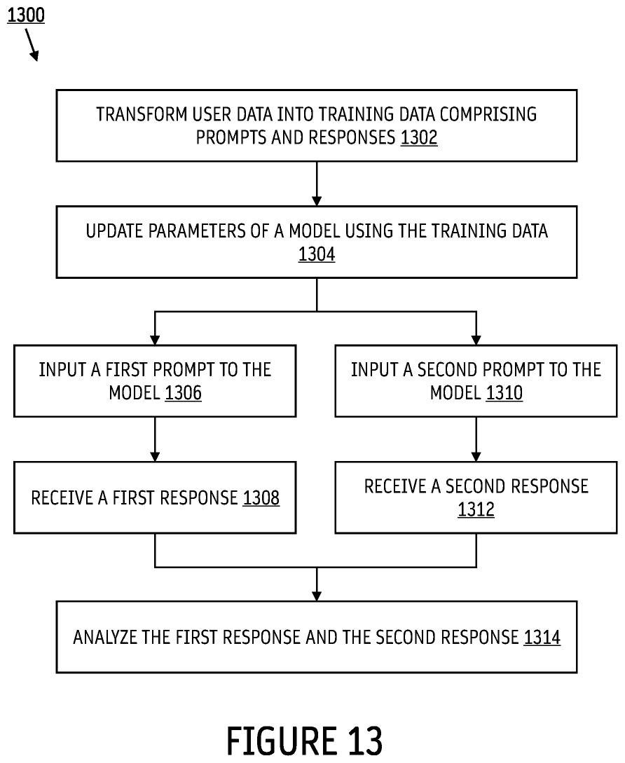

FIG. 13 is a flow chart illustrating methods for training a model, and analyzing responses from the model, according to some embodiments of the disclosure. Method 1300 is illustrated.

In 1302, user data may be transformed into training data. The user data may include data collected from a content streaming platform, and user communication data. The user data may include market research data, and/or user research data. The training data may include prompts and responses to the prompts.

In 1304, parameters of a model may be updated using the training data.

In 1306, a first prompt may be input to the model. The first prompt may include a first description of a first persona, a context description, and a question.

In 1308, a first response may be received from the model in response to the first prompt.

In 1310, a second prompt may be input to the model. The second prompt may include a second description of a second persona different from the first persona, the context description, and the question.

In 1312, a second response may be received from the model in response to the second prompt.

1306 and 1310 may be performed serially (in different orders) or in parallel. In 1314, the first response and the second response may be analyzed.

In some embodiments, training data corresponding to different personae may have different weights. The weights may be used in 1304.

In some embodiments, the distribution of training data associated with different personae may be balanced to ensure that training data for a particular persona does not dominate.

### Exemplary Methods for Cluster Analysis and Exploration

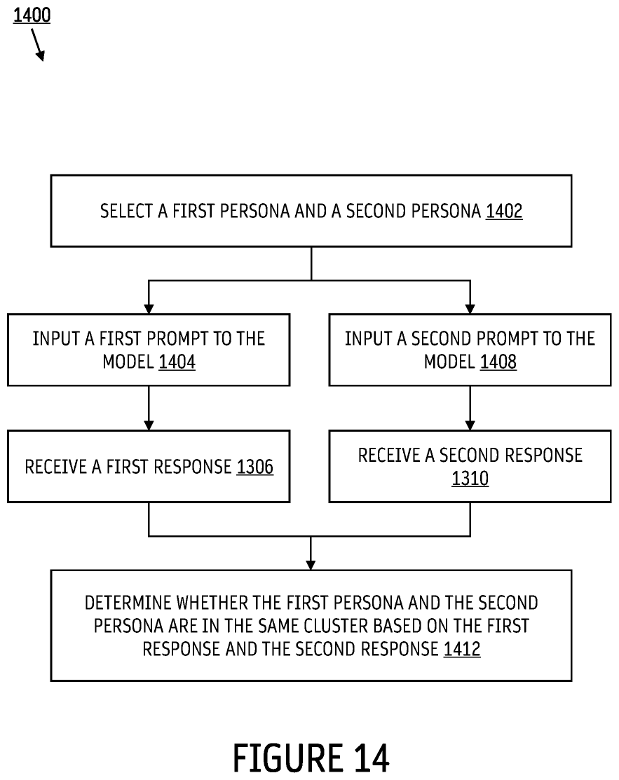

FIG. 14 is a flow chart illustrating methods for exploratory cluster analysis, according to some embodiments of the disclosure. Method 1400 is illustrated.

In 1402, a first persona and a second persona are selected.

In 1404, a first prompt may be input to a model. The first prompt may include a first description of a first persona, a first context description, and a first question, and the model being trained using one or more of: data collected from a content streaming platform, and user communication data, market research data, and user research data.

In 1406, a first response may be received from the model in response to the first prompt. The first response may include a first feature vector that represents the first persona's response to the first context description and the first question.

In 1408, a second prompt may be input to the model. The second prompt can include a second description of a second persona different from the first persona, the first context description, and the first question.

In 1410, a second response may be received from the model in response to the second prompt. The second response may include a second feature vector that represents the second persona's response to the first context description and the first question. 1

1404 and 1408 may be performed serially (in different orders) or in parallel.

In 1412, method 1400 may include determining whether the first persona and the second persona are in a same cluster based on the first response and the second response.

In some embodiments, the method 1400 includes varying personae, to explore clusters of synthetic users, or determine cohorts of synthetic users that may respond similarly or dissimilarly.

In some embodiments, method 1400 includes varying other aspects, such as the context description, and/or the question, to explore clusters of synthetic users, or determine cohorts of synthetic users that may respond similarly or dissimilarly.

In some embodiments, the method 1400 may iteratively vary different aspects to gather a range of feedback from synthetic users under different conditions (e.g., context description, questions, etc.). The range of feedback that can be used and examined for cluster analysis in an exploratory manner.

### Exemplary Analysis for Content Understanding, e.g., Marking Cue Points for Content Injection

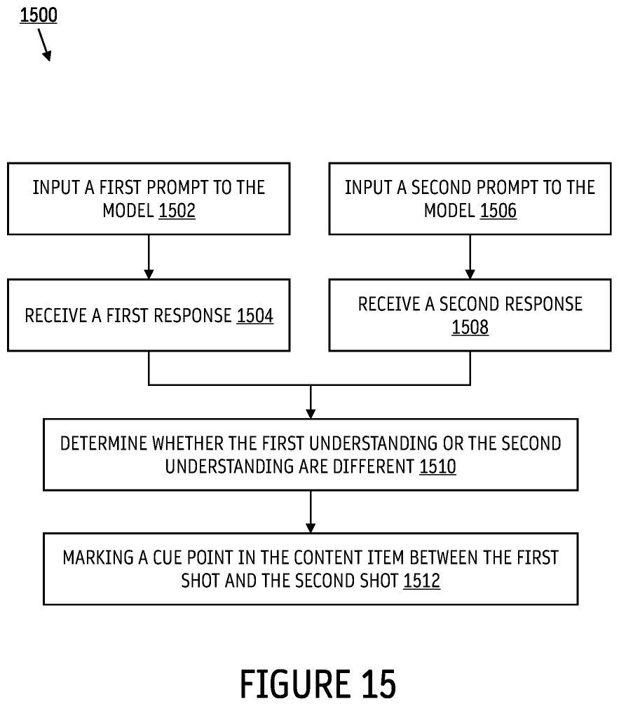

FIG. 15 is a flow chart illustrating methods for content understanding, according to some embodiments of the disclosure. Method 1500 is illustrated.

In 1502, a first prompt may be input to a model. The first prompt may include a first description of a first persona, a first description of a first shot of a content item, and a question. The model may be trained using one or more of: data collected from a content streaming platform, user communication data, market research data, and user research data.

In 1504, a first response may be received from the model in response to the first prompt. The first response may indicate a first understanding of the first shot description by the first persona. The first response may include a first feature vector of the first prompt.

In 1506, a second prompt may be input to the model. The first prompt may include the first description of a first persona, a second description of a second shot of the content item following the first shot, and the question.

In 1508, a second response may be received from the model in response to the second prompt. The second response may indicate a second understanding of the second shot description by the first persona. The second response may include a second feature vector of the second prompt.

1502 and 1506 may be performed serially (in different orders) or in parallel.

In 1510, the method may include determining whether the first understanding and the second understanding are different.

In 1512, in response to determining that the first understanding and the second understanding are different (e.g., indicating a natural scene ending), a cue point may be marked in the content item between the first shot and the second shot as a location to insert content.

In some embodiments, the model may be used to determine one or more of: a reaction, sentiment, predicted economic gain response, and understanding of the content being inserted at the cue point. The model may receive a prompt having a description of the persona, a description of the content to be inserted at the cue point, and a question. The model may generate a response that indicates a positive reaction to the content. The model may generate a response that indicates a positive sentiment to the content. The model may generate a response that indicates a positive economic gain response to the content.

In some embodiments, the content to be inserted at the cue point may correspond to the first understanding and/or the second understanding.

### Exemplary Methods for Building Synthetic User Memories

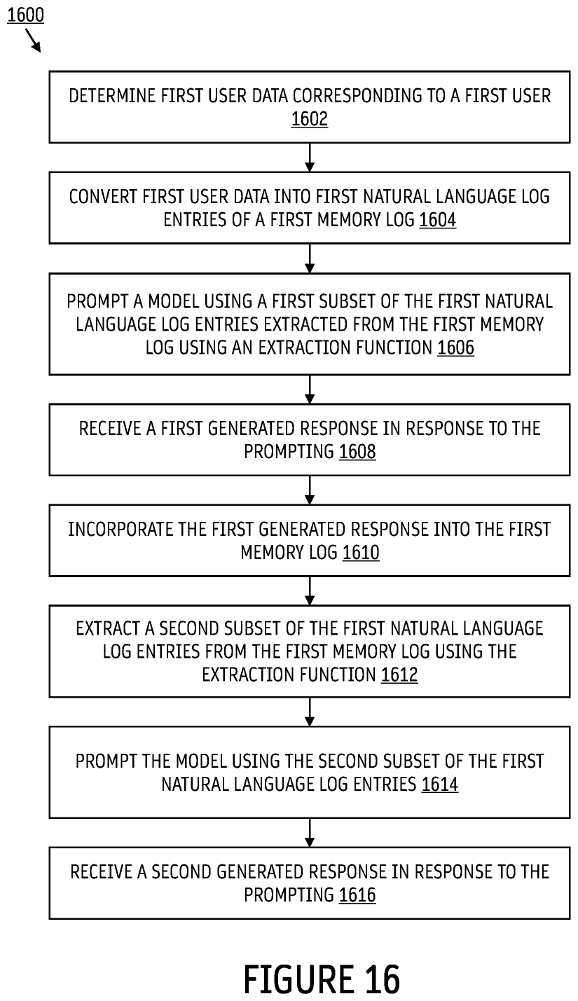

FIG. 16 is a flow chart illustrating methods for prompt chaining to create synthetic user memories, according to some embodiments of the disclosure. Method 1600 is illustrated.

In 1602, first user data corresponding to a first user of, e.g., a content streaming platform may be determined.

In 1604, the first user data may be converted into first natural language log entries of a first memory log,

In 1606, a model may be prompted using (e.g., may receive an input comprising) a first subset of the first natural language log entries extracted from the first memory log using an extraction function.

In 1608, a first generated response may be received from the model in response to prompting using the first subset;

In 1610, the first generated response may be incorporated into the first memory log.

In 1612, after incorporating the first generated response, a second subset of the first natural language log entries may be extracted from the first memory log using the extraction function.

In 1614, the model may be prompted using e.g., may receive an input comprising) the second subset of the first natural language log entries.

In 1616, a second generated response may be received from the model in response to the prompting using the second subset.

### Exemplary Methods for Refining Synthetic User Memories

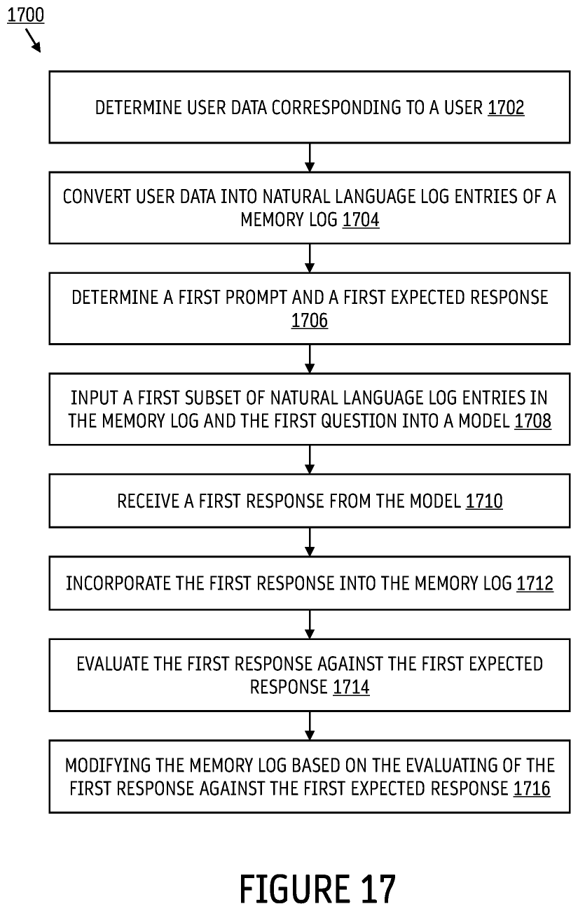

FIG. 17 is a flow chart illustrating methods for refining synthetic user memories, according to some embodiments of the disclosure. Method 1700 is illustrated.

In 1702, user data corresponding to a user of, e.g., a content streaming platform, may be determined.

In 1704, the user data may be converted into natural language log entries of a memory log.

In 1706, a first question and a first expected response to the first question may be determined from the user data.

In 1708, a first subset of natural language log entries in the memory log and the first question may be input into a model.

In 1710, a first generated response may be received from the model in response to the inputting of the first subset and the first question into the model.

In 1712, the first generated response may be incorporated into the memory log;

In 1714, the first generated response may be evaluated against the first expected response.

In 1716, the memory log may be modified based on the evaluating of the first generated response against the first expected response.

### Exemplary Methods for Using Synthetic Users to Complete an Experiment

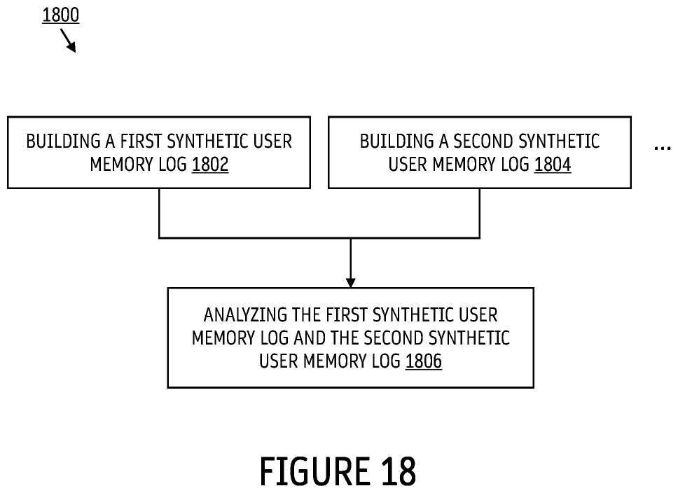

FIG. 18 is a flow chart illustrating methods for completing an experiment such as an A/B feature test, according to some embodiments of the disclosure. Method 1800 is illustrated.

In 1802, a first synthetic user memory log may be built.

In 1802, building the first synthetic user memory log may include determining first user interactivity data corresponding to a first user of a content streaming platform logged during an experiment. The first user may belong to a first group of users exposed to a first feature of the content streaming platform. Building the first synthetic user memory log may include converting the first user interactivity data into first natural language log entries of the first synthetic user memory log. Building the first synthetic user memory log may include inputting, into a model, a first subset of the first natural language log entries in the first synthetic user memory log and a first request to generate a first response representing a first predicted action of the first user based on the first subset of the first natural language log entries. Building the first synthetic user memory log may include adding the generated first response into the first synthetic user memory log.

In 1804, a second synthetic user memory log may be built.

In 1804, building the second synthetic user memory log may include determining second user interactivity data corresponding to a second user of the content streaming platform logged during the experiment. The second user may belong to a second group of users exposed to a second feature of the content streaming platform. Building the second synthetic user memory log may include converting the second user interactivity data into second natural language log entries of the second synthetic user memory log. Building the second synthetic user memory log may include inputting, into the model, a second subset of the second natural language log entries in the second memory log and a second request to generate a second response representing a second predicted action the second user based on the second subset of the second natural language log entries. Building the second synthetic user memory log may include adding the generated second response into the second synthetic user memory log.

1802 and 1804 can be performed for additional users, e.g., building more synthetic user memory logs using other users' data.

In 1806, the first synthetic user memory log and the second synthetic user memory log may be analyzed to determine effects of the first feature and the second feature.

### Exemplary Computing Device

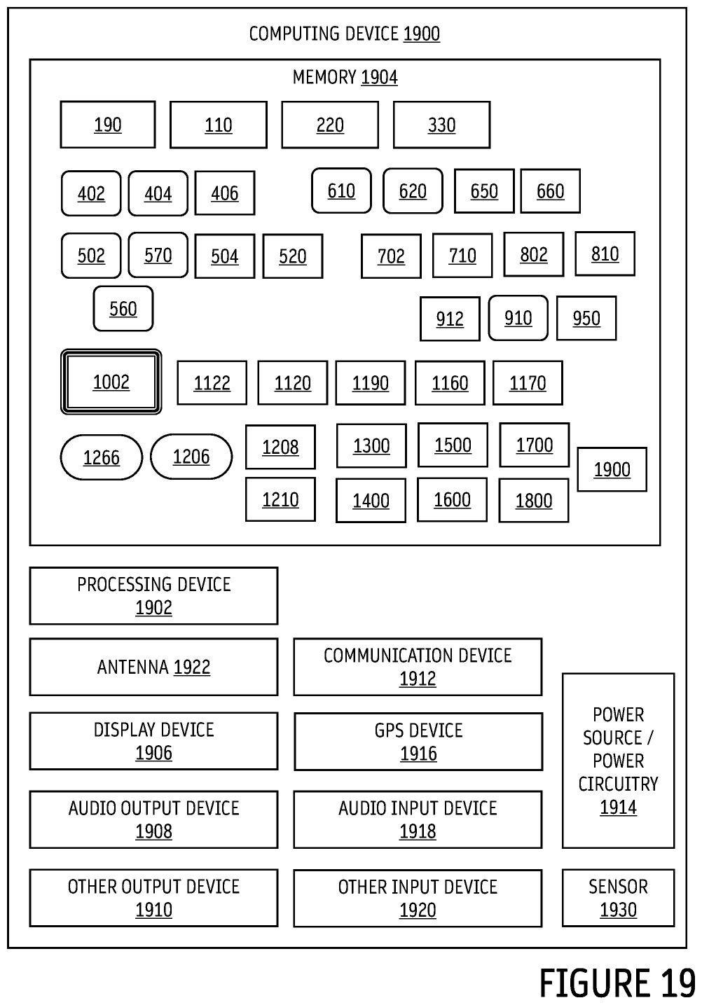

FIG. 19 is a block diagram of an exemplary computing device 1900, according to some embodiments of the disclosure. One or more computing devices 1900 may be used to implement the functionalities described with the FIGURES and herein. A number of components are illustrated in the FIGURES as included in the computing device 1900, but any one or more of these components may be omitted or duplicated, as suitable for the application. In some embodiments, some or all of the components included in the computing device 1900 may be attached to one or more motherboards. In some embodiments, some or all of these components are fabricated onto a single system on a chip (SoC) die. Additionally, in various embodiments, the computing device 1900 may not include one or more of the components illustrated in FIG. 19, and the computing device 1900 may include interface circuitry for coupling to the one or more components. For example, the computing device 1900 may not include a display device 1906, and may include display device interface circuitry (e.g., a connector and driver circuitry) to which a display device 1906 may be coupled. In another set of examples, the computing device 1900 may not include an audio input device 1918 or an audio output device 1908 and may include audio input or output device interface circuitry (e.g., connectors and supporting circuitry) to which an audio input device 1918 or audio output device 1908 may be coupled.

The computing device 1900 may include a processing device 1902 (e.g., one or more processing devices, one or more of the same type of processing device, one or more of different types of processing device). The processing device 1902 may include electronic circuitry that process electronic data from data storage elements (e.g., registers, memory, resistors, capacitors, quantum bit cells) to transform that electronic data into other electronic data that may be stored in registers and/or memory. Examples of processing device 1902 may include a central processing unit (CPU), a graphical processing unit (GPU), a quantum processor, a machine learning processor, an artificial-intelligence processor, a neural network processor, an artificial-intelligence accelerator, an application specific integrated circuit (ASIC), an analog signal processor, an analog computer, a microprocessor, a digital signal processor, a field programmable gate array (FPGA), a tensor processing unit (TPU), a data processing unit (DPU), etc.

The computing device 1900 may include a memory 1904, which may itself include one or more memory devices such as volatile memory (e.g., DRAM), nonvolatile memory (e.g., read-only memory (ROM)), high bandwidth memory (HBM), flash memory, solid state memory, and/or a hard drive. Memory 1904 includes one or more non-transitory computer-readable storage media. In some embodiments, memory 1904 may include memory that shares a die with the processing device 1902. In some embodiments, memory 1904 includes one or more non-transitory computer-readable media storing instructions executable to perform operations described with the FIGURES and herein, such as the methods illustrated in FIGURES. Exemplary parts that may be encoded as instructions and stored in memory 1904 are depicted. Memory 1904 may store instructions that encode one or more exemplary parts. The instructions stored in the one or more non-transitory computer-readable media may be executed by processing device 1902. In some embodiments, memory 1904 may store data, e.g., data structures, binary data, bits, metadata, files, blobs, etc., as described with the FIGURES and herein. Exemplary data that may be stored in memory 1904 are depicted. Memory 1904 may store one or more data as depicted.

In some embodiments, the computing device 1900 may include a communication device 1912 (e.g., one or more communication devices). For example, the communication device 1912 may be configured for managing wired and/or wireless communications for the transfer of data to and from the computing device 1900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not. The communication device 1912 may implement any of a number of wireless standards or protocols, including but not limited to Institute for Electrical and Electronic Engineers (IEEE) standards including Wi-Fi (IEEE 1902.10 family), IEEE 1902.16 standards (e.g., IEEE 1902.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1902.16 compatible Broadband Wireless Access (BWA) networks are generally referred to as WiMAX networks, an acronym that stands for worldwide interoperability for microwave access, which is a certification mark for products that pass conformity and interoperability tests for the IEEE 1902.16 standards. The communication device 1912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication device 1912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication device 1912 may operate in accordance with Code-division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication device 1912 may operate in accordance with other wireless protocols in other embodiments. The computing device 1900 may include an antenna 1922 to facilitate wireless communications and/or to receive other wireless communications (such as radio frequency transmissions). The computing device 1900 may include receiver circuits and/or transmitter circuits. In some embodiments, the communication device 1912 may manage wired communications, such as electrical, optical, or any other suitable communication protocols (e.g., the Ethernet). As noted above, the communication device 1912 may include multiple communication chips. For instance, a first communication device 1912 may be dedicated to shorter-range wireless communications such as Wi-Fi or Bluetooth, and a second communication device 1912 may be dedicated to longer-range wireless communications such as global positioning system (GPS), EDGE, GPRS, CDMA, WiMAX, LTE, EV-DO, or others. In some embodiments, a first communication device 1912 may be dedicated to wireless communications, and a second communication device 1912 may be dedicated to wired communications.

The computing device 1900 may include power source/power circuitry 1914. The power source/power circuitry 1914 may include one or more energy storage devices (e.g., batteries or capacitors) and/or circuitry for coupling components of the computing device 1900 to an energy source separate from the computing device 1900 (e.g., DC power, AC power, etc.).

The computing device 1900 may include a display device 1906 (or corresponding interface circuitry, as discussed above). The display device 1906 may include any visual indicators, such as a heads-up display, a computer monitor, a projector, a touchscreen display, a liquid crystal display (LCD), a light-emitting diode display, or a flat panel display, for example.

The computing device 1900 may include an audio output device 1908 (or corresponding interface circuitry, as discussed above). The audio output device 1908 may include any device that generates an audible indicator, such as speakers, headsets, or earbuds, for example.

The computing device 1900 may include an audio input device 1918 (or corresponding interface circuitry, as discussed above). The audio input device 1918 may include any device that generates a signal representative of a sound, such as microphones, microphone arrays, or digital instruments (e.g., instruments having a musical instrument digital interface (MIDI) output).

The computing device 1900 may include a GPS device 1916 (or corresponding interface circuitry, as discussed above). The GPS device 1916 may be in communication with a satellite-based system and may receive a location of the computing device 1900, as known in the art.

The computing device 1900 may include a sensor 1930 (or one or more sensors). The computing device 1900 may include corresponding interface circuitry, as discussed above). Sensor 1930 may sense physical phenomenon and translate the physical phenomenon into electrical signals that can be processed by, e.g., processing device 1902. Examples of sensor 1930 may include: capacitive sensor, inductive sensor, resistive sensor, electromagnetic field sensor, light sensor, camera, imager, microphone, pressure sensor, temperature sensor, vibrational sensor, accelerometer, gyroscope, strain sensor, moisture sensor, humidity sensor, distance sensor, range sensor, time-of-flight sensor, pH sensor, particle sensor, air quality sensor, chemical sensor, gas sensor, biosensor, ultrasound sensor, a scanner, etc.

The computing device 1900 may include another output device 1910 (or corresponding interface circuitry, as discussed above). Examples of the other output device 1910 may include an audio codec, a video codec, a printer, a wired or wireless transmitter for providing information to other devices, haptic output device, gas output device, vibrational output device, lighting output device, home automation controller, or an additional storage device.

The computing device 1900 may include another input device 1920 (or corresponding interface circuitry, as discussed above). Examples of the other input device 1920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1900 may have any desired form factor, such as a handheld or mobile computer system (e.g., a cell phone, a smart phone, a mobile Internet device, a music player, a tablet computer, a laptop computer, a netbook computer, a personal digital assistant (PDA), an ultramobile personal computer, a remote control, wearable device, headgear, eyewear, footwear, electronic clothing, etc.), a desktop computer system, a server or other networked computing component, a printer, a scanner, a monitor, a set-top box, an entertainment control unit, a vehicle control unit, a digital camera, a digital video recorder, an Internet-of-Things device (e.g., light bulb, cable, power plug, power source, lighting system, audio assistant, audio speaker, smart home device, smart thermostat, camera monitor device, sensor device, smart home doorbell, motion sensor device), a virtual reality system, an augmented reality system, a mixed reality system, or a wearable computer system. In some embodiments, the computing device 1900 may be any other electronic device that processes data.

### SELECT EXAMPLES

Example 1 provides a method, including transforming user data into training data, the user data including data collected from a content streaming platform, and user communication data, and the training data including prompts and responses to the prompts; updating parameters of a model using the training data; inputting a first prompt to the model, the first prompt including a first description of a first persona, a context description, and a question; receiving a first response from the model in response to the first prompt; inputting a second prompt to the model, the second prompt including a second description of a second persona different from the first persona, the context description, and the question; receiving a second response from the model in response to the second prompt; and analyzing the first response and the second response.
Example 2 provides the method of example 1, where: training data associated with the first persona has a first weight; training data associated with the second persona has a second weight; and optimizing parameters of the model using the first weight and the second weight.
Example 3 provides the method of example 1 or 2, further including balancing distribution of training data associated with the first persona and training data associated with the second persona.
Example 4 provides a method, including selecting a first persona and a second persona; inputting a first prompt to a model, the first prompt including a first description of a first persona, a first context description, and a first question, and the model being trained using one or more of: data collected from a content streaming platform, user communication data, market research data, and user research data; receiving a first response from the model in response to the first prompt; inputting a second prompt to the model, the second prompt including a second description of a second persona different from the first persona, the first context description, and the first question; receiving a second response from the model in response to the second prompt; and determine whether the first persona and the second persona are in a same cluster based on the first response and the second response.
Example 5 provides the method of example 4, further including inputting a third prompt to a model, the third prompt including the first description of the first persona, a second context description, and the first question; receiving a third response from the model in response to the third prompt; inputting a fourth prompt to the model, the fourth prompt including the second description of the second persona different from the first persona, the second context description, and the first question; and receiving a fourth response from the model in response to the fourth prompt; and determining whether the first persona and the second persona are in the same cluster further based on the third response and the fourth response.
Example 6 provides the method of example 4 or 5, further including inputting a fifth prompt to a model, the fifth prompt including the first description of the first persona, the first context description, and a second question, receiving a fifth response from the model in response to the fifth prompt; inputting a sixth prompt to the model, the sixth prompt including the second description of the second persona different from the first persona, the first context description, and the second question; and receiving a sixth response from the model in response to the sixth prompt; and determining whether the first persona and the second persona are in the same cluster further based on the fifth response and the sixth response.
Example 7 provides a method, including inputting a first prompt to a model, the first prompt including a first description of a first persona, a first description of a first shot of a content item, and a question, and the model being trained using one or more of: data collected from a content streaming platform, user communication data, market research data, and user research data; receiving a first response from the model in response to the first prompt, the first response indicating a first understanding of the first description of the first shot of the content item by the first persona; inputting a second prompt to the model, the first prompt including the first description of a first persona, a second description of a second shot of the content item following the first shot, and the question; receiving a second response from the model in response to the second prompt, the second response indicating a second understanding of the second description of the second shot of the content item by the first persona; determining whether the first understanding and the second understanding are different; and in response to determining that the first understanding and the second understanding are different, marking a cue point in the content item between the first shot and the second shot as a location to insert content.
Example 8 provides the method of example 7, further including inputting a third prompt to the model, the third prompt including the first description of the first persona, a third description of the content, and a further question; and receiving a third response from the model in response to the third prompt, the third response indicating a positive reaction to the content.
Example 9 provides the method of example 7, further including inputting a third prompt to the model, the third prompt including the first description of the first persona, a third description of the content, and a further question; and receiving a third response from the model in response to the third prompt, the third response indicating a positive sentiment to the content.
Example 10 provides the method of example 7, further including inputting a third prompt to the model, the third prompt including the first description of the first persona, a third description of the content, and a further question; and receiving a third response from the model in response to the third prompt, the third response indicating a positive economic gain response to the content.
Example 11 provides the method of any one of examples 7-10, where the first understanding of the first shot corresponds to the content being inserted at the cue point.
Example 12 provides a method, including determining first user data corresponding to a first user of a content streaming platform; converting the first user data into first natural language log entries of a first memory log; prompting a model using a first subset of the first natural language log entries extracted from the first memory log using an extraction function; receiving a first generated response in response to prompting using the first subset; incorporating the first generated response into the first memory log; after incorporating the first generated response, extracting a second subset of the first natural language log entries from the first memory log using the extraction function; prompting the model using the second subset of the first natural language log entries; and receiving a second generated response in response to the prompting using the second subset.
Example 13 provides the method of example 12, further including incorporating the second generated response into the first memory log.
Example 14 provides the method of example 12 or 13, where the extraction function includes a scoring function that scores the first natural language log entries based on freshness and accuracy.
Example 15 provides the method of example 14, where the accuracy is measured based on an evaluation of a response generated by the model against the first user data.
Example 16 provides the method of any one of examples 12-15, where the extraction function includes a selection function that selects one or more responses generated by the model.
Example 17 provides the method of any one of examples 12-16, where prompting the model using the first subset of the first natural language log entries includes inputting a question and the first subset of the first natural language log entries to the model to generate an opinion about the first subset of the first natural language log entries.
Example 18 provides the method of any one of examples 12-17, where prompting the model using the first subset of the first natural language log entries includes inputting a question and the first subset of the first natural language log entries to the model to generate a statement about the first subset of the first natural language log entries and a reasoning behind the statement.
Example 19 provides the method of any one of examples 12-18, further including determining second user data corresponding to a second user of the content streaming platform; and converting the second user data into second natural language log entries of a second memory log; and incorporating one or more third responses generated by the model using one or more second natural language log entries of the second memory log into the second memory log.
Example 20 provides the method of example 19, further including analyzing (1) a response generated by the model in response to a test question and one or more first natural language log entries of the first memory log, and (2) a response generated by the model in response to the test question and one or more second natural language log entries of the second memory log.
Example 21 provides the method of any one of examples 12-20, where the first user data includes demographic information about the first user, one or more survey questions, and one or more survey answers.
Example 22 provides the method of any one of examples 12-21, where the first user data includes user interactivity data of the first user on the content streaming platform logged during an experiment.
Example 23 provides the method of example 22, where the converting includes translating user interactivity data into natural language descriptions of the user interactivity data.
Example 24 provides a method, including determining user data corresponding to a user of a content streaming platform; converting the user data into natural language log entries of a memory log; determining a first question and a first expected response to the first question from the user data; inputting a first subset of natural language log entries in the memory log and the first question into a model; receiving a first generated response from the model in response to the inputting of the first subset and the first question into the model; incorporating the first generated response into the memory log; evaluating the first generated response against the first expected response; and modifying the memory log based on the evaluating of the first generated response against the first expected response.
Example 25 provides the method of example 24, where: the first question includes a survey question to the user; and the first expected response includes a survey response to the survey question provided by the user.
Example 26 provides the method of example 24 or 25, where: the first question includes user interactivity data corresponding to a first time frame; and the first expected response includes user interactivity data corresponding to a second time frame, the second time frame being after the first time frame.
Example 27 provides the method of any one of examples 24-26, where the evaluating includes determining accuracy of the first generated response based on the first expected response.
Example 28 provides the method of any one of examples 24-27, where the modifying includes setting an accuracy score of the first generated response in the memory log based on the evaluating, where the accuracy score is used in subsequent extraction of one or more subsets of natural language log entries for prompting the model.
Example 29 provides the method of any one of example 24-28, where the modifying includes removing the first generated response from the memory log.
Example 30 provides the method of any one of example 24-29, where the modifying includes removing the first generated response, the first question, and the first expected response from the memory log.
Example 31 provides the method of any one of example 24-30, further including determining a second question and a second expected response to the second question from the user data; inputting a second subset of natural language log entries of the memory log and the second question into the model; receiving a second generated response from the model in response to the inputting; and incorporating the second generated response into the memory log.
Example 32 provides the method of example 31, further including evaluating the second generated response against the second expected response; and modifying the memory log based on the evaluating of the second generated response against the second expected response.
Example 33 provides a method including building a first synthetic user memory log, including determining first user interactivity data corresponding to a first user of a content streaming platform logged during an experiment, where the first user belongs to a first group of users exposed to a first feature of the content streaming platform; converting the first user interactivity data into first natural language log entries of the first synthetic user memory log; inputting, into a model, a first subset of the first natural language log entries in the first synthetic user memory log and a first request to generate a first response representing a first predicted action of the first user based on the first subset of the first natural language log entries; and adding the first response into the first synthetic user memory log; building a second synthetic user memory log, including determining second user interactivity data corresponding to a second user of the content streaming platform logged during the experiment, where the second user belongs to a second group of users exposed to a second feature of the content streaming platform; converting the second user interactivity data into second natural language log entries of the second synthetic user memory log; inputting, into the model, a second subset of the second natural language log entries in the second synthetic user memory log and a second request to generate a second response representing a second predicted action the second user based on the second subset of the second natural language log entries; and adding the second response into the second synthetic user memory log; and analyzing the first synthetic user memory log and the second synthetic user memory log to determine effects of the first feature and the second feature.
Example 34 provides the method of example 33, where the analyzing includes converting one or more natural language log entries in first synthetic user memory log into a first quantitative metric about the first feature; and converting one or more natural language log entries in second synthetic user memory log into a second quantitative metric about the second feature.
Example 35 provides the method of example 33 or 34, where building the first synthetic user memory log further includes inputting, into the model, a third subset of the first natural language log entries of the first synthetic user memory log and a question to generate a first quantitative metric about the third subset of the first natural language log entries; and adding the first quantitative metric into the first synthetic user memory log.
Example 36 provides the method of any one of examples 33-35, where: the first request further includes a first instruction to generate a first reasoning for the first predicted action; and the second request further includes a second instruction to generate a second reasoning for the second predicted action.
Example 37 provides the method of any one of examples 33-36, where: the first request further includes a third instruction to identify one or more first natural language log entries in the first subset that led to the first predicted action; and the second request further includes a fourth instruction to identify one or more second natural language log entries in the second subset that led to the second predicted action.
Example 38 provides the method of any one of examples 33-37, further including in response to determining that a difference in the effects of the first feature and the second feature is statistically significant based on the first synthetic user memory log, the second synthetic user memory log, and further synthetic user memories, halting further inputting to the model.
Example 39 provides the method of any one of examples 33-38, further including in response to determining that the first synthetic user memory log and the second synthetic user memory log have reached a certain size, halting further inputting to the model.
Example 40 provides the method of any one of examples 33-39, where building the first synthetic user memory log further includes inputting, into the model, a fourth subset of the first natural language log entries of the first synthetic user memory log, and a description of a test stimulus; generating a third response of the first user based on the fourth subset of the first natural language log entries and the test stimulus; and adding the third response into the first synthetic user memory log.
Example 41 provides one or more non-transitory computer-readable media storing instructions that, when executed by one or more processors, cause the one or more processors to perform any one of the methods provided in Examples 1-40.
Example 42 provides an apparatus comprising means to carry out or means for carrying out any one of the computer-implemented methods provided in Examples 1-40.
Example 43 provides a computer-implemented system, comprising one or more processors, and one or more non-transitory computer-readable media storing instructions that, when executed by the one or more processors, cause the one or more processors to perform any one of the methods provided in Examples 1-40.

### Variations and Other Notes

The detailed description provides various examples of the embodiments disclosed herein.

The detailed description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the detailed description.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

Further, references are made to the accompanying drawings that form a part hereof, and in which are shown, by way of illustration, embodiments that may be practiced. It is to be understood that other embodiments may be utilized, and structural or logical changes may be made without departing from the scope of the present disclosure. Therefore, the detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed or described operations may be omitted in additional embodiments.

For the purposes of the present disclosure, the phrase “A or B” or the phrase “A and/or B” means (A), (B), or (A and B). For the purposes of the present disclosure, the phrase “A, B, or C” or the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side” to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking or in any other manner.

In the detailed description, various aspects of the illustrative implementations will be described using terms commonly employed by those skilled in the art to convey the substance of their work to others skilled in the art.

The terms “substantially,” “close,” “approximately,” “near,” and “about,” generally refer to being within +/−20% of a target value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value as described herein or as known in the art.

In addition, the terms “comprise,” “comprising,” “include,” “including,” “have,” “having” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods and devices of this disclosure each have several innovative aspects, no single one of which is solely responsible for all desirable attributes disclosed herein. Details of one or more implementations of the subject matter described in this specification are set forth in the description and the accompanying drawings.

What is claimed is:

1. A method, comprising:
inputting a first prompt to a model, the first prompt comprising a first description of a first persona, a first description of a first shot of a content item, and a question, and the model being trained using one or more of: data collected from a content streaming platform, user communication data, market research data, and user research data;
receiving a first response from the model in response to the first prompt, the first response indicating a first understanding of the first description of the first shot of the content item by the first persona;
inputting a second prompt to the model, the first prompt comprising the first description of a first persona, a second description of a second shot of the content item following the first shot, and the question;
receiving a second response from the model in response to the second prompt, the second response indicating a second understanding of the second description of the second shot of the content item by the first persona;
determining whether the first understanding and the second understanding are different; and
in response to determining that the first understanding and the second understanding are different, marking a cue point in the content item between the first shot and the second shot as a location to insert content.

2. The method of claim 1, further comprising:
inputting a third prompt to the model, the third prompt comprising the first description of the first persona, a third description of the content, and a further question; and
receiving a third response from the model in response to the third prompt, the third response indicating a positive reaction to the content.

3. The method of claim 1, further comprising:
inputting a third prompt to the model, the third prompt comprising the first description of the first persona, a third description of the content, and a further question; and
receiving a third response from the model in response to the third prompt, the third response indicating a positive sentiment to the content.

4. The method of claim 1, further comprising:
inputting a third prompt to the model, the third prompt comprising the first description of the first persona, a third description of the content, and a further question; and
receiving a third response from the model in response to the third prompt, the third response indicating a positive economic gain response to the content.

5. The method of claim 1, wherein the first understanding of the first shot corresponds to the content being inserted at the cue point.

6. A computer-implemented system, comprising:
one or more processors; and
one or more non-transitory computer-readable media storing instructions that, when executed by the one or more processors, cause the one or more processors to:
determine first user data corresponding to a first user of a content streaming platform;
convert the first user data into first natural language log entries of a first memory log;
prompt a model using a first subset of the first natural language log entries extracted from the first memory log using an extraction function;
receive a first generated response in response to prompting using the first subset;
incorporate the first generated response into the first memory log;
after incorporating the first generated response, extract a second subset of the first natural language log entries from the first memory log using the extraction function;
prompt the model using the second subset of the first natural language log entries; and
receive a second generated response in response to the prompting using the second subset.

7. The computer-implemented system of claim 6, wherein the instructions, when executed by the one or more processors, further cause the one or more processors to:
incorporate the second generated response into the first memory log.

8. The computer-implemented system of claim 6, wherein the extraction function comprises:
a scoring function that scores the first natural language log entries based on freshness and accuracy.

9. The computer-implemented system of claim 8, wherein the accuracy is measured based on an evaluation of a response generated by the model against the first user data.

10. The computer-implemented system of claim 6, wherein the extraction function comprises:
a selection function that selects one or more responses generated by the model.

11. The computer-implemented system of claim 6, wherein the one or more processors to prompt the model using the first subset of the first natural language log entries comprises:
the one or more processors to input a question and the first subset of the first natural language log entries to the model to generate an opinion about the first subset of the first natural language log entries.

12. The computer-implemented system of claim 6, wherein the one or more processors to prompt the model using the first subset of the first natural language log entries comprises:
the one or more processors to input a question and the first subset of the first natural language log entries to the model to generate a statement about the first subset of the first natural language log entries and a reasoning behind the statement.

13. The computer-implemented system of claim 6, wherein the instructions, when executed by the one or more processors, further cause the one or more processors to:
determine second user data corresponding to a second user of the content streaming platform; and
convert the second user data into second natural language log entries of a second memory log; and
incorporate one or more third responses generated by the model using one or more second natural language log entries of the second memory log into the second memory log.

14. The computer-implemented system of claim 13, wherein the instructions, when executed by the one or more processors, further cause the one or more processors to:
analyzing (1) a response generated by the model in response to a test question and one or more first natural language log entries of the first memory log, and (2) a response generated by the model in response to the test question and one or more second natural language log entries of the second memory log.

15. The computer-implemented system of claim 6, wherein the first user data comprises demographic information about the first user, one or more survey questions, and one or more survey answers.

16. The computer-implemented system of claim 6, wherein the first user data comprises user interactivity data of the first user on the content streaming platform logged during an experiment.

17. The computer-implemented system of claim 16, wherein the one or more processors to convert the first user data into the first natural language log entries of the first memory log comprises:
the one or more processors to translate the user interactivity data into natural language descriptions of the user interactivity data.

18. One or more non-transitory computer-readable media storing instructions that, when executed by one or more processors, cause the one or more processors to:
transform user data into training data, the user data comprising data collected from a content streaming platform, and user communication data, and the training data comprising prompts and responses to the prompts;
update parameters of a model using the training data;
input a first prompt to the model, the first prompt comprising a first description of a first persona, a context description, and a question;
receive a first response from the model in response to the first prompt;
input a second prompt to the model, the second prompt comprising a second description of a second persona different from the first persona, the context description, and the question;
receive a second response from the model in response to the second prompt; and
analyze the first response and the second response.

19. The one or more non-transitory computer-readable media of claim 18, wherein the instructions, when executed by the one or more processors, further cause the one or more processors to:
train data associated with the first persona has a first weight;
train data associated with the second persona has a second weight; and
optimize parameters of the model using the first weight and the second weight.

20. The one or more non-transitory computer-readable media of claim 18, wherein the instructions, when executed by the one or more processors, further cause the one or more processors to:
balance distribution of training data associated with the first persona and training data associated with the second persona.
